(19) United States
(12) Patent Application Publication
(10) Pub. No.: US 2017/0242949 A1
(43) Pub. Date: Aug. 24, 2017

(54) TRANSISTOR MODEL, A METHOD FOR A COMPUTER BASED DETERMINATION OF CHARACTERISTIC OF A TRANSISTOR, A DEVICE AND A COMPUTER READABLE STORAGE MEDIUM FOR PERFORMING THE METHOD

(71) Applicant: INFINEON TECHNOLOGIES AUSTRIA AG, VILLACH (AT)

(72) Inventors: Patrick Schindler, Munich (DE); Katarzyna Kowalik-Seidl, Munich (DE); Franz Hirler, Isen (DE)

(21) Appl. No.: 15/431,841

(22) Filed: Feb. 14, 2017

(30) Foreign Application Priority Data
Feb. 18, 2016 (DE) 10 2016 102 875.4

(51) Int. Cl. G06F 17/50

(52) U.S. Cl. CPC G06F 17/5036; H01L 29/7804

(57) ABSTRACT

According to various embodiments, a transistor model for a computer based simulation of a field effect transistor may include: a first electrical network coupled between a drain node, a source node and a gate node, wherein the first electrical network is configured to represent an electrical characteristic of the field effect transistor in a forward operation; a second electrical network coupled parallel to the first electrical network and between the source node and the drain node, wherein the second electrical network is configured to represent an electrical characteristic of the field effect transistor in at least one of a commutation operation and a reverse operation; wherein the second electrical network includes: a controlled first source representing a parasitic junction of the field effect transistor; at least one controlled second source representing a charge injection dependent parasitic impedance of the field effect transistor; wherein the controlled first source and the at least one controlled second source are coupled in parallel; and wherein the controlled first source and the at least one controlled second source are coupled via at least one parameter such that a charge injection from the parasitic junction into the parasitic impedance is considered.

### CROSS-REFERENCE TO RELATED APPLICATION

This application claims priority to German Patent Application Serial No. 10 2016 102 875.4, which was filed Feb. 18, 2016, and is incorporated herein by reference in its entirety.

### TECHNICAL FIELD

Various embodiments relate generally to a transistor model, a method for a computer based determination of a characteristic of a transistor, a device, and a computer readable storage medium for performing the method.

### BACKGROUND

In general, semiconductor circuit elements may be processed in semiconductor technology on or in a substrate (also referred to as a wafer or a carrier), e.g. to fabricate integrated circuits (also referred to as chips). The properties of a semiconductor circuit element depend on various details, such as the specific semiconductor technology, the geometry, the size, the physical structure, the used materials, the driving frequency, the driving mode, etc. Several parasitic effects may alter the properties of the semiconductor circuit element, such as parasitic current paths, parasitic capacitances, and parasitic switches.

For fabrication, it is a general concern to find strategies for reproducing, designing, scaling, calculating and prototyping a particular semiconductor circuit element, such as a transistor, e.g. before and/or after fabrication. Conventional strategies are limited in their reliability and accuracy and/or need significant effort to be performed. For example, conventional strategies are merely accurate in a particular driving mode, for one particular aspect and/or up to a particular complexity/size of the semiconductor circuit element; or they are even unsuitable to consider the real physical parameters, to scale them, or to adapt them. For example, a conventional compact diode model may simulate individual aspects of diodes such as capacity or switching behavior.

Therefore, for a determination of characteristics of a transistor, a combination of conventionally theories, models, and methods is necessary in order to consider each and every aspect of the transistor. However, commonly substantial doubts remain about origin and correlation of various properties, e.g. in view of the physical parameters of the transistor.

By reducing those doubts and/or increasing the level of accuracy, maldevelopment and malfunction of the fabricated transistors, as well as the cost connected to the fabrication and development may be reduced. Further, a specific design and development, e.g. in view of particular requirements, may be facilitated.

### SUMMARY

According to various embodiments, a transistor model for a computer based simulation of a field effect transistor may include: a first electrical network coupled between a drain node, a source node and a gate node, wherein the first electrical network is configured to represent an electrical characteristic of the field effect transistor in a forward operation; a second electrical network coupled parallel to the first electrical network and between the source node and the drain node, wherein the second electrical network is configured to represent an electrical characteristic of the field effect transistor in at least one of a commutation operation and a reverse operation; wherein the second electrical network includes: a controlled first source representing a parasitic junction of the field effect transistor; at least one controlled second source representing a charge injection dependent parasitic impedance of the field effect transistor; wherein the controlled first source and the at least one controlled second source are coupled in parallel; and wherein the controlled first source and the at least one controlled second source are coupled via at least one parameter such that a charge injection from the parasitic junction into the parasitic impedance is considered.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a transistor in a schematic cross sectional view or side view according to various embodiments;

FIG. 2 shows an electrical network or an equivalent sub-circuit according to various embodiments;

FIG. 3 shows a transistor model according to various embodiments;

FIGS. 4 to 8 respectively show an electrical network according to various embodiments;

FIG. 9 shows a transistor model according to various embodiments;

FIGS. 10 to 13 respectively show an electrical network according to various embodiments;

FIG. 14 shows a transistor model according to various embodiments;

FIGS. 15 and 16 respectively show an electrical network according to various embodiments;

FIG. 17 shows a method according to various embodiments;

FIG. 18 shows a computer readable storage medium according to various embodiments;

FIG. 19 shows a device according to various embodiments;

FIG. 20 shows a commutation circuit model according to various embodiments;

FIGS. 21 to 29 respectively show a method according to various embodiments;

FIG. 30 shows a computer readable storage medium according to various embodiments;

FIG. 31 shows a device according to various embodiments;

FIG. 32 shows an electrical network according to various embodiments;

FIG. 33 shows a programmable electrical element according to various embodiments;

FIG. 34 shows a transistor model according to various embodiments;

FIGS. 35 and 36 respectively show an electrical characteristic according to various embodiments;

FIG. 37 shows a transistor model according to various embodiments;

FIGS. 38 and 39 respectively show an electrical characteristic according to various embodiments;

FIG. 40 shows a transistor model according to various embodiments;

FIG. 41 shows a transistor model according to various embodiments;

FIGS. 42 to 44 respectively show an electrical characteristic according to various embodiments;

FIG. 45 shows a transistor according to various embodiments;

FIGS. 46 and 47 respectively show an electrical network according to various embodiments;

FIG. 48 shows a transistor model according to various embodiments; and

FIG. 49 shows a commutation circuit model according to various embodiments; and

FIGS. 50 and 51 respectively show an electrical network according to various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

According to various embodiments, the transistor may include a semiconductor material, e.g. at least one of doped and undoped. The transistor may be formed in or on a substrate. The substrate may include or be formed from the semiconductor material. According to various embodiments, at least one of a substrate and a semiconductor region may include or be formed from a semiconductor material of various types, including a group IV semiconductor (e.g. silicon or germanium), a compound semiconductor, e.g. a group III-V compound semiconductor (e.g. gallium arsenide or gallium nitride), a group II-VI compound semiconductor or other types, including group III semiconductors, group V semiconductors or polymers, for example. In an embodiment, at least one of the substrate and the semiconductor region is made of silicon (doped or undoped), in an alternative embodiment, at least one of the substrate and the semiconductor region is a silicon on insulator (SOI) wafer. As an alternative, any other suitable semiconductor material can be used for at least one of the substrate and the semiconductor region, for example a semiconductor compound material such as gallium phosphide (GaP), indium phosphide (InP), but also any suitable ternary semiconductor compound material or quaternary semiconductor compound material such as indium gallium arsenide (InGaAs) or gallium nitride (GaN).

According to various embodiments, an electrical energy source (simplified also referred to as source) may be understood as generating or absorbing electric energy (e.g. in form of current or voltage). For example, the electrical energy source may absorb electric energy by generating a reversed electric energy thereto. The electric energy absorbed or generated by the electrical energy source may be dependent on a controller parameter supplied to the electrical energy source (in this case also referred to as controlled electrical energy source). The correlation between controller parameter and the electric energy generated or absorbed by the electrical energy source may be described by an electrical characteristic. For example, if the controller parameter includes or is formed from a voltage, the electrical characteristic may be an energy-voltage characteristic.

According to various embodiments, an electrical characteristic may be configured in accordance with a physical circuit element (e.g. like a physical resistor, physical capacitor, physical inductance, current source, voltage source, etc.). In this case, the electrical energy source may represent the physical circuit element. In other words, the electrical energy source may imitate properties of the physical circuit element (e.g. its current-voltage-characteristic).

According to various embodiments, an electrical energy source may be configured for generating or absorbing an electrical current (also referred to as current) through the electrical energy source (in this case also referred to as current source). The electrical current absorbed or generated by the current source may be dependent on the controller parameter supplied to the current source (in this case also referred to as controlled current source).

According to various embodiments, a voltage source may be configured for maintaining an electrical voltage (also referred to as voltage) across (over) the voltage source. The electrical voltage maintained by the voltage source may be dependent on a controller parameter supplied to the voltage source (also referred to as controlled voltage source).

An electrical energy source may be modeled via a programmable circuit element. The programmable circuit element may be programed with at least one electrical characteristic to generate or absorb electric energy in accordance with the electrical characteristic. The electrical characteristic may represent the correlation of two parameters, of which at least one is an electrical parameter (e.g. electrical current, electrical voltage, electrical capacitance, electrical inductance, electrical impedance, electrical resistance, or the like). The electrical characteristic may represent the correlation of an output parameter and one is a controller parameter. The output parameter may define or be the output of the programmable circuit element (e.g. a source).

By way of example, the electrical characteristic may include or be formed from a current-voltage characteristic, a current-time characteristic, a resistance-frequency characteristic, a resistance-voltage characteristic, or the like. Illustratively, the programmable circuit element may be programed to imitate the properties of a physical circuit element having the electrical characteristic. In other words, the electrical energy source modeled by the programmable circuit element may represent the physical circuit element.

Active electrical elements (such as a transistor) may be modeled by a controlled (electric energy, e.g. current or voltage) source. For example, a bipolar transistor may be modeled by a controlled current source from the collector to the emitter, with the current controlled by a base-emitter voltage (the controller parameter).

The programmable circuit element may be part of a programmable network element. The programmable network element may include one or more programmable circuit elements and optionally one or more non-programmable circuit elements (having predefined properties, like a resistor having a static resistance).

According to various embodiments, a model and method are provided, which enable to simulate a storage charging characteristic of a transistor. For example, scaling the current (current scaling) and/or scaling the area (area scaling) of the transistor may be provided with a high accuracy by the model and the method. The temporal characteristic of the current, e.g. the drain current, may be reproduced by the model and method with a high physical level of correctness.

According to various embodiments, the simulation accuracy for a diode characteristic of the transistor may be improved, e.g. by considering a parasitic npn-structure (e.g., a parasitic bipolar transistor). According to various embodiments, a parasitic bipolar transistor may be used for modeling the parasitic npn-structure. Alternatively or additionally to the npn-structure, a parasitic pnp-structure may be considered. In general, the parasitic pnp-structure and/or the parasitic npn-structure may be also referred to as parasitic bipolar-junction (e.g., a parasitic bipolar transistor). Using the parasitic bipolar transistor may enable to approximate the physical attributes of the parasitic bipolar-junction by a minimized effort (e.g., reducing simulation time). Alternatively or additionally, a more complex abstract object may be used for approximating the bipolar-junction, e.g., considering electrical field proximate the gate terminal. For example, the more complex abstract object may contribute to the current flow through the physical transistor. This may enable and facilitate correct simulation of complex circuit structures including the transistor, e.g. which are driven in a diode operation mode and/or in a commutation operation mode.

According to various embodiments, the structure of the provided model and method are configured to be added to various conventional transistor models, e.g. without disturbing their functionality (e.g. in a forward operation). Illustratively, the provided model and method may be combined with other commonly used models and methods, thus reducing modification and implementation effort.

According to various embodiments, a transistor may be one of various types of a transistors, such as among others may be a bipolar transistor (BJT), a heterojunction BJP, a Schottky BJP, an insulated-gate BJP (also referred to as IGBT), a field-effect transistor (FET), a junction field-effect transistor, a metal-oxide-semiconductor field-effect transistor (MOSFET), a dual-gate MOSFET, a fast-reverse or fast-recovery epitaxial diode FET, a heterostructure insulated gate FET, a modulation-doped FET, a tunnel FET, an insulated-gate bipolar transistor (IGBT), a super-junction MOSFET and the like. In dependency of the specific semiconductor technology in which a transistor is fabricated, various materials are processed for forming the corresponding layers. For example, a transistor may be processed in complementary metal-oxide-semiconductor (CMOS) technology and/or in double-diffused metal-oxide-semiconductor (DMOS) technology.

According to various embodiments, the transistor may a power transistor, e.g. including one or more power transistor cells (also referred to as CoolMOS cells). A power transistor may be used as a switch or rectifier in power electronics. In power electronics, such a device may be also called a power device or, when used in an integrated circuit, a power integrated circuit (power IC). The transistor, e.g. the power transistor, may be operated in “commutation mode” (also referred to as commutation operation), for example, operated in a two-state mode (e.g. on or off).

According to various embodiments, the model may simulated by running a program, e.g. a program based on Spice (Simulation Program with Integrated Circuit Emphasis), e.g. PSpice. The program may be configured for circuit simulation. For example, the program may be configured for simulation of integrated circuit and/or board-level design, e.g. to check the integrity of circuit designs and/or to predict circuit behavior. The program may be configured to perform a network analysis based on the model. The program may be at least one of executed by a processor and represented by code segments.

According to various embodiments, the transistor model may include a compact diode model. Illustratively, the compact diode model itself may be limited in simulation accuracy. For example, a significant deviation of the diode characteristic from a measurement may occur, e.g. in particular increasing with increasing current flow. On the other hand, an area scaling may be not supported by the compact diode model. According to various embodiments, a parasitic bipolar-junction (e.g., a parasitic bipolar transistor) is considered, e.g. in addition to compact diode model. This enables to correct the stored charge in the transistor, which may by overestimated or underestimated by merely using the compact diode model.

Alternatively or additionally, the model and the method may consider a body-diode of the transistor (in this case also referred to as body diode model). For example, the model and the method may enable determination of a characteristic of a transistor in a body diode operation.

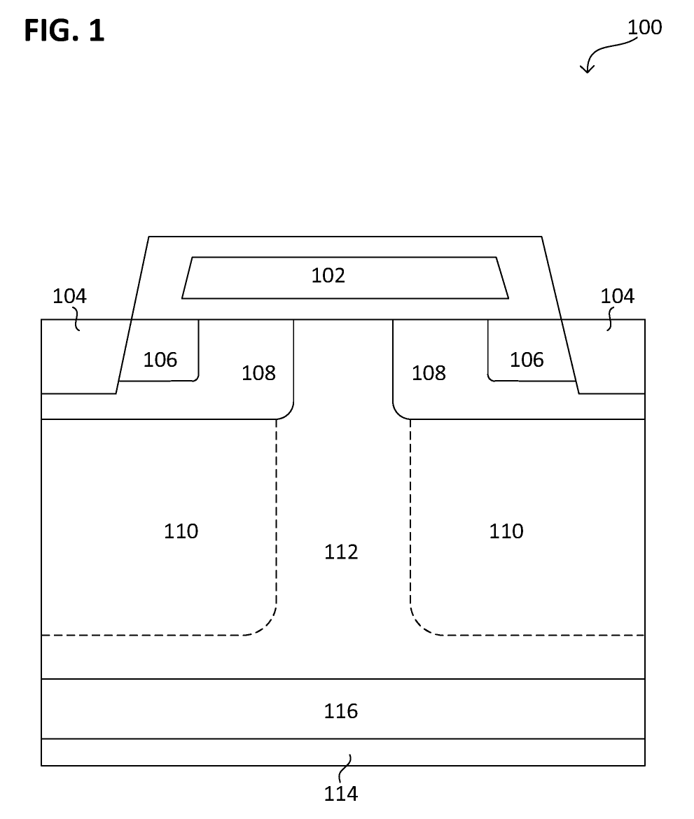

FIG. 1 illustrates a transistor cell 100 in a schematic cross sectional view or side view according to various embodiments, showing its physical structure. The transistor may include a gate contact 102, a drain contact 114, and a source contact 104. Further, the transistor 100 may include the following doped regions (doped semiconductor regions): a first doped region 106, a second doped region 108 and third doped region 112. Optionally, the transistor 100 may include at least one of a fourth doped region 110 and a fifth doped region 116. The fourth doped region 110 may also be referred to doping pillar 110. The fourth doped region 110 may be present in a super junction transistor 100. The fifth doped region 116 may also be referred to as collector region 116.

The first doped region 106, the third doped region 112 and the fifth doped region 116 may be doped by a first doping type (e.g. n-type). The second doped region 108 and the fourth doped region 110 may be doped by a second doping type (e.g. p-type), different from the first doping type. The second doped region 108 may be doped more than the fourth doped region 110. At least one of the first doped region 106 and the fifth doped region 116 may be doped more than the third doped region 112.

According to various embodiments, the transistor 100 (e.g. a MOSFET) may be a super-junction MOSFET, e.g. based on a charge-balance principle. Illustratively, the super-junction may include a thick drift region 112 of the MOSFET. The thick drift region 112 may be heavily doped (e.g. by electrons, also referred to as n-doped region), thereby reducing the electrical resistance to electron flow (also referred to as track resistance) without compromising the breakdown voltage of the MOSFET. The drift region 112 may be juxtaposed with a region 110 that is similarly doped with the opposite carrier polarity (e.g. holes, also referred to as p-doped region). These two similar, but oppositely doped regions 110, 112 may cancel out their mobile charge and may form a depleted region in between. The depleted region may support a high voltage during the off-state. On the other hand, during the on-state, the higher doping of the drift region 112 may be configured to facilitate the flow of charge carriers (e.g. electrons and/or holes), e.g. thereby reducing on-resistance (also referred to as on-state resistance).

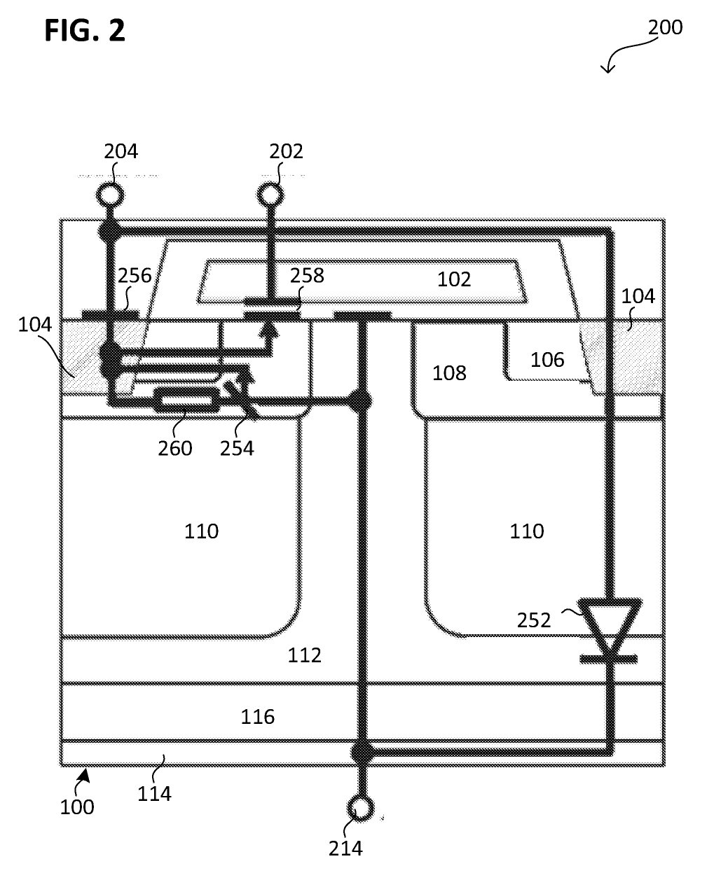

FIG. 2 illustrates an electrical network 200 or an equivalent sub-circuit 200 according to various embodiments in a schematic circuit diagram, overlaying the physical structure of the transistor 100 for illustration. Illustratively, the electrical network 200 represents the physical structure of the transistor 100. The electrical network 200 may illustrate one or more parasitic junctions of the transistor 100 (also referred to as polar-junctions of the transistor 100).

The electrical network 200 may include a first node 202 representing the gate contact 102 (also referred to as gate node 202), a second node 214 representing the drain contact 114 (also referred to as drain node 214), and a third node 204 representing the source contact 104 (also referred to as source node 204).

The electrical network 200 may include a first parasitic element 252, e.g. defined by a pn-interface (illustratively, an interface between two doped regions differing in their doping type). The first parasitic element 252 defined by a pn-interface may be also referred to as unipolar junction 252 (e.g. pn-junction or np-junction). For example, the first parasitic element 252 may be a diode.

The electrical network 200 may include a second parasitic element 254, e.g. defined by a bipolar-interface (illustratively, a doped region between two other doped regions differing in their doping type from the doped region), e.g. a pnp-interface or npn-interface. The second parasitic element 254 defined by a bipolar-interface may be also referred to as bipolar-junction 254, e.g. npn-junction 254 or pnp-junction 254. For example, the first parasitic element 252 may be a parasitic npn-structure and/or parasitic pnp-structure (e.g., a parasitic bipolar transistor) of the transistor 100. The second parasitic element 254 may include a resistive part of a parasitic impedance of the transistor 100. The resistive part of the parasitic impedance (also referred to as parasitic resistance or resistive impedance) may depend on a charge carrier injection by the first parasitic element 252. Illustratively, a current through the first parasitic element 252 may inject carriers into the second parasitic element 254 thereby reducing the parasitic resistance.

The first parasitic element 252 and the second parasitic element 254 may differ from each other, e.g. by at least one of size, number of junctions, number of doped regions, and electrical characteristic (e.g. voltage-current-characteristic).

The electrical network 200 may include a third parasitic element 256, e.g. defined by a parasitic charge storage capability (illustratively, between the second node 214 and the third node 204). The third parasitic element 256 may include a capacitance, e.g. illustratively, represented by a capacitor between the source node 204 and the drain node 214 in FIG. 2.

The third parasitic element 256 may consider the electrical charge flowing when reversing the polarity between the second node 214 and the third node 204 (e.g. in a commutation operation). The third parasitic element 256 may consider a plurality of parasitic sub-capacitances, each occurring at a unipolar-interface of the transistor 200 (e.g. adjacent to the first parasitic element 252). The third parasitic element 256 may consider a parasitic unipolar-interface capacitance.

The third parasitic element 256 may include a capacitive part of a parasitic impedance of the transistor 100. The capacitive part of the parasitic impedance (also referred to as parasitic capacitance or capacitive impedance) may depend on a charge carrier injection by the first parasitic element 252. Illustratively, a current through the first parasitic element 252 may inject carriers into the second parasitic element 254 thereby reducing the parasitic capacitance.

At least one of the second parasitic element 254 and the third parasitic element 256 may include or be formed from a parasitic impedance (e.g. at least one of resistive impedance and a capacitive impedance) of the transistor 200 which depends on a carrier injection through the first parasitic element 252. At least one of the second parasitic element 254 and the third parasitic element 256 may include or be formed from a parasitic impedance of the transistor 200 which depends on a current through the first parasitic element 252.

The electrical network 200 may include a fourth parasitic element 258, e.g. defined by a parasitic charge storage capability (illustratively, between the third node 204 and the first node 202). The fourth parasitic element 258 may include a capacitance, e.g. represented by a capacitor. The fourth parasitic element 258 may consider the electrical charge flowing when reversing the polarity between the third node 204 and the first node 202. The fourth parasitic element 258 may consider a parasitic gate-source capacitance. In analogy, further fourth parasitic elements may be considered, e.g. at least one of a parasitic drain-source capacitance and a parasitic gate-drain capacitance.

A diode current of the transistor 100 may be defined by the current flowing through the first parasitic element 252 and the second parasitic element 254.

The electrical network 200 may include a fifth parasitic element 260, e.g. defined by a parasitic resistance (illustratively, between the second parasitic element 254 and the third node 204). The fifth parasitic element 260 may include a resistor.

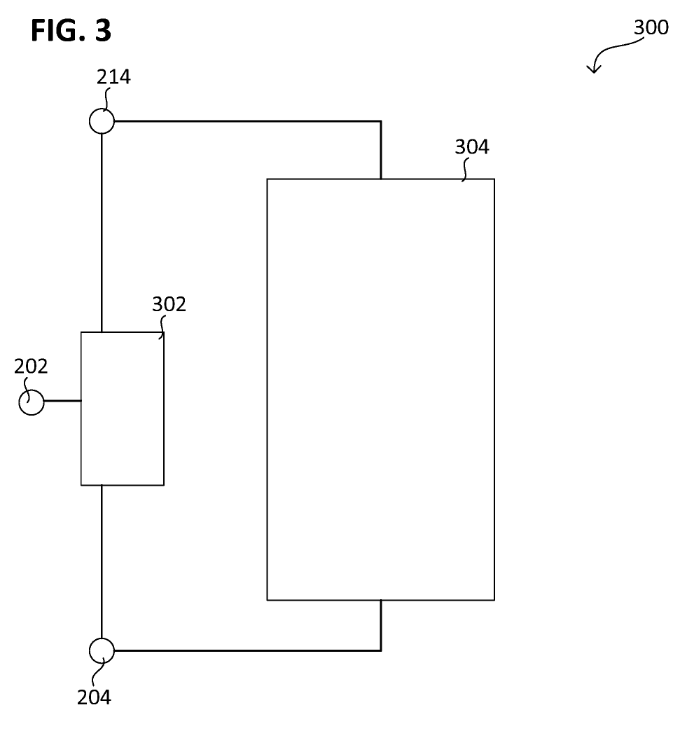

FIG. 3 illustrates a transistor model 300 in a schematic circuit diagram according to various embodiments.

The transistor model 300 may include a first electrical network 302 coupled between a drain node 214, a source node 204 and a gate node 202. The first electrical network 302 may be configured to represent a switching characteristic of a transistor (e.g. transistor 100, e.g. a field effect transistor) in a forward operation, e.g. controlled by the gate node 202. The switching characteristic may be defined by an electric potential applied to the gate node 202. For example, the switching characteristic may be defined by an electric voltage (electric potential difference) between the gate node 202 an at least one of the drain node 214 and the source node 204. Illustratively, the first electrical network 302 may represent, e.g. model, a voltage driven switch, e.g. in the forward operation.

In the forward operation, a forward current may flow between the drain node 214 and the source node 204, e.g. through the first electrical network 302, e.g. only through the first electrical network 302. In the forward operation, an electric potential of the drain node 214 may be less than an electric potential of the source node 204.

The transistor model 300 may further include a second electrical network 304 coupled parallel to the first electrical network 302 and between the source node 204 and the drain node 214. The second electrical network 304 may be configured to represent a switching characteristic of the transistor in a commutation operation and/or in a reverse operation.

In the reverse operation (also referred to as diode operation), a reverse current (also referred to as diode current) may flow between the drain node 214 and the source node 204, e.g. through the second electrical network 304, e.g. only through the second electrical network 304. In the reverse operation, the electric potential of the drain node 214 may be more than the electric potential of the source node 204.

In the commutation operation, the operation of the transistor is changed between reverse operation and forward operation. In other words, during the commutation operation, the polarity of an electric voltage between the drain node 214 and the source node 204 is changed (e.g. inverted).

In the reverse operation, the first electrical network 302 may block a current flow through the first electrical network 302. In other words, the first electrical network 302 may be configured to have an infinitely resistance in reverse operation. In the forward operation, the second electrical network 304 may block a current flow through the second electrical network 304.

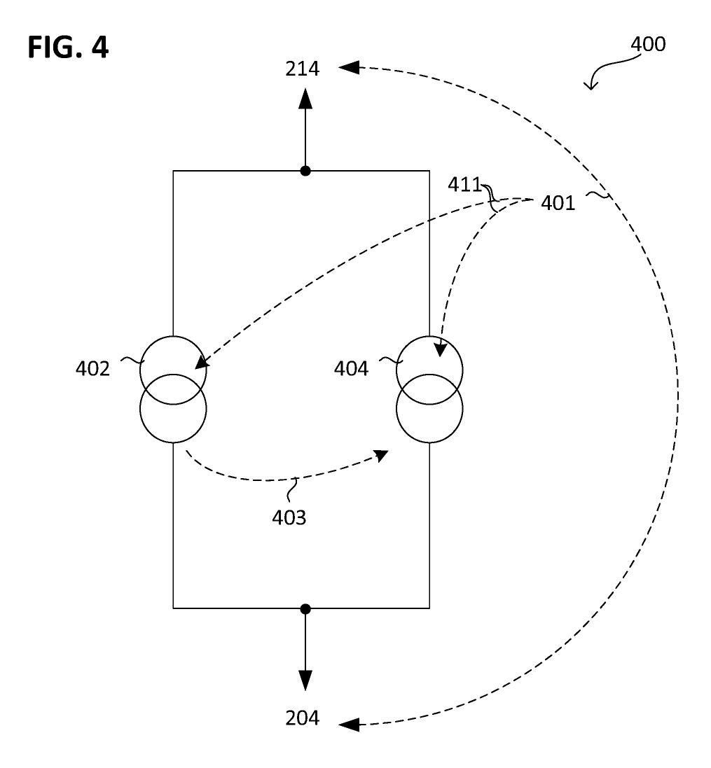

FIG. 4 illustrates a second electrical network 400 in a schematic circuit diagram according to various embodiments.

According to various embodiments, the second electrical network 400 may include a controlled first electrical energy source 402 (also referred to as controlled first source 402), e.g. a controlled first current source 402. Further, the second electrical network 400 may include a controlled second electrical energy source 404 (also referred to as controlled second source 404), e.g. a controlled second current source 404, coupled in parallel to the first electrical energy source 402.

The first electrical energy source 402 (in the following exemplarily first current source 402) and the second electrical energy source 404 (in the following exemplarily second current source 404) may be coupled between the drain node 214 and the source node 204.

The first current source 402 may represent the first parasitic element (e.g. a unipolar junction, e.g. a diode) of the transistor (e.g. a field effect transistor). The second current source 404 may represent a second parasitic element (e.g. a bipolar-junction, e.g. a parasitic npn-structure and/or parasitic npn-structure (e.g., a parasitic bipolar transistor) of the transistor. Illustratively, the transistor may be understood as physical transistor the model represents.

According to various embodiments, the first current source 402 and the second current source 404 may be configured to generate a current depending on the first parameter 401 (also referred to as first controlling parameter 401). In other words, the first current source 402 and the second current source 404 may be controlled 411 by the first parameter 401. The first parameter 401 may be an electrical parameter, e.g. the voltage over the respective current source 402, 404.

The first parameter 401 may represent (e.g. be identical or a function of) a voltage between the source node 204 and the drain node 214. For example, the first parameter 401 may be a function of the voltage between the source node 204 and the drain node 214. For example, the first parameter 401 may be an electric current from the source node 204 to drain node 214. Alternatively or additionally, the first parameter 401 may represent (e.g. be identical or a function of) at least one of the polarity and the voltage between the source node 204 and the drain node 214.

By way of example, the first current source 402 may represent a diode. In this context, the first current source 402 may be configured to generate a current defined by an electrical characteristic of the diode (e.g. in dependency on a first parameter 401, e.g. a voltage over the first current source 402). For example, the electrical characteristic of the diode may be defined by a shottky characteristic (e.g. using the Shottky Equation).

Alternatively or additionally, the second current source 404 may be configured to generate a current depending on a second parameter 403 (also referred to as second control parameter 403). In other words, the second current source 404 may be controlled 411 by the second parameter 403. The second parameter 403 may be an electrical parameter. The second parameter 403 may represent the voltage between the source node 204 and the drain node 214 (also referred to as source-drain-voltage), e.g. via the first current source 402. The second current source 404 may generate a current (output) in accordance with a second electrical characteristic. The second electrical characteristic may correlate the output of the second current source 404 to at least one of the first parameter 401 and the second parameter 403. By way of example, the second electrical characteristic may correlate a resistivity of the second current source 404 (defining the output to the first parameter 401) and the second parameter 403 to each other (illustratively, a controlled resistor).

By way of example, the second current source 404 may represent a parasitic npn-structure and/or parasitic npn-structure (e.g., a parasitic bipolar transistor). In other words, the second current source 404 may generate a current defined by an electrical characteristic of the parasitic npn-structure and/or parasitic npn-structure (e.g., the parasitic bipolar transistor). The current generated by the second current source 404 may be configured to depend on a first parameter 401, e.g. a voltage over the second current source 404, and a second parameter 403. The second parameter 403 may represent (e.g. be identical or a function of) a current generated by the first current source 402. Illustratively, the second parameter 403 may represent (e.g. be identical or a function of) an electric current through the first parasitic element.

According to various embodiments, the two parameters 401, 403 (also referred to as controlling parameters) may be correlated to each other, e.g. via a function. Illustratively, the first parameter 401 may be a function of (in other words, depending on, e.g. be identical with) the voltage between the source node 204 and the drain node 214 (also referred to as source-drain-voltage). Further, the second parameter 403 may be a function of the first parameter 401, e.g. via the first current source 402 (illustratively, its electrical characteristic), and therefore represent the source-drain-voltage. A parameter representing another parameter may be understood as functional correlation, e.g. via one function or more than one functions (e.g. enclosing each other), e.g. a chain of functions.

An electrical characteristic may be understood as correlating two parameters to each other, e.g. via a function. For example, an electrical characteristic may correlate a voltage and a current to each other, and, therefore represent a resistance dependent on at least one of the current and the voltage. According to various embodiments, an electrical characteristic may define a correlation of two electrical parameters, e.g. of an electric current through an element, device, or material, and the corresponding voltage (potential difference) across it. Alternatively or additionally, at least one of the two electrical parameters may be a current density, an electrical field strength, and/or an electrical charge.

At least one of the first parameter 401 and the second parameter 403 may consider a coupling between the first parasitic element and the second parasitic element. For example, the electrical characteristic of the first source 402 (also referred to as first electrical characteristic) may correlate the first parameter 401 with the second parameter 403. In other words, the first electrical characteristic may correlate the first parameter 401 to a second parameter 403.

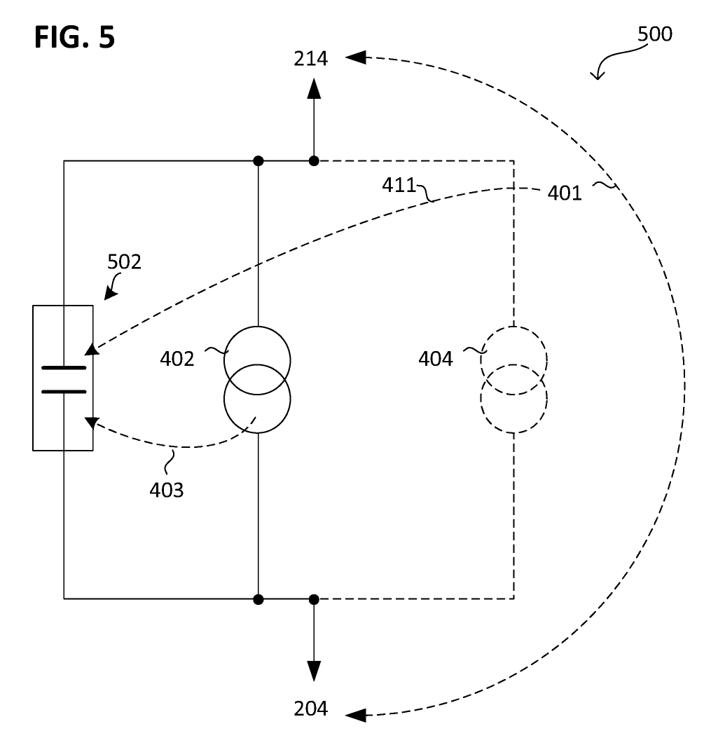

FIG. 5 illustrates a second electrical network 500 in a schematic circuit diagram according to various embodiments, similar to the second electrical network described before.

In the second electrical network 500, the second source 404 may be optional.

The second electrical network 500 may further include a controlled capacitance component 502 (also referred to controlled Crr) coupled in parallel to the first current source 402 and the second current source 404. The controlled capacitance component 502 may be coupled between the drain node 214 and the source node 204. The controlled capacitance component 502 may represent the third parasitic element, e.g. a parasitic capacitance of the transistor (e.g. a field effect transistor), e.g. a capacitance of the first parasitic element.

Illustratively, the second electrical network 500 may be configured to consider a controlled charging and/or discharging of the capacitance 502.

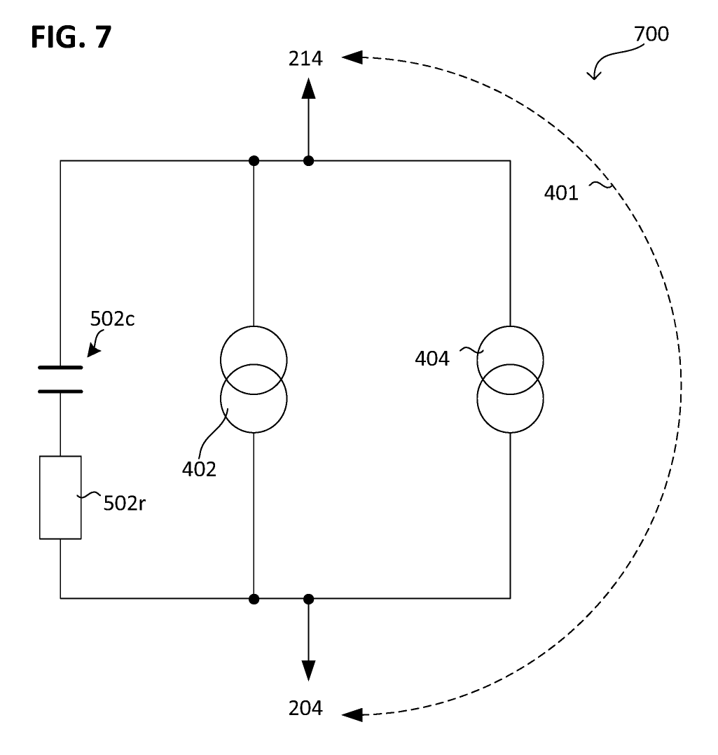

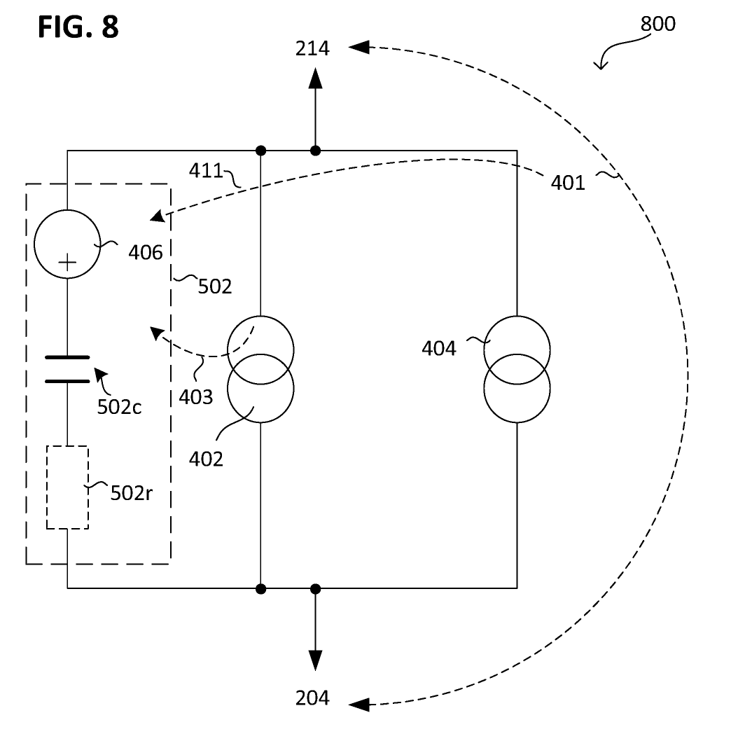

The controlled capacitance component 502 may include at least a capacitor 502c and a controlled third electrical energy source 406 (see for example, FIG. 8). Optionally, the controlled capacitance component 502 may include a first resistor 502r (see for example, FIG. 7). Optionally, the controlled capacitance component 502 may include a charging controller network (also referred to as third network) considering time and/or operation mode dependency of the third parasitic element 256. The third parasitic element 256 may be a capacitive component of the first parasitic element 252.

The controlled capacitance component 502 (the capability for electrostatic storage of charge induced by voltage) may consider a capacitive part of the impedance (capacitive impedance) of the first parasitic element 252. The resistive part of the impedance (resistivity) of the first parasitic element 252 may be considered at least by the first current source 402.

The controlled capacitance component 502 may be controlled by the first parameter 401. The controlled capacitance component 502 may be configured to provide a capacitance in dependency of the first parameter 401 (e.g. a voltage over the controlled capacitance component 502). Alternatively or additionally, the controlled capacitance component 502 may be controlled by the second parameter 401.

At least one of the first parameter 401 and the second parameter 403 may consider a coupling between the first parasitic element and the third parasitic element. For example, the electrical characteristic of the first source 402 (also referred to as first electrical characteristic) may correlate the first parameter 401 with the second parameter 403.

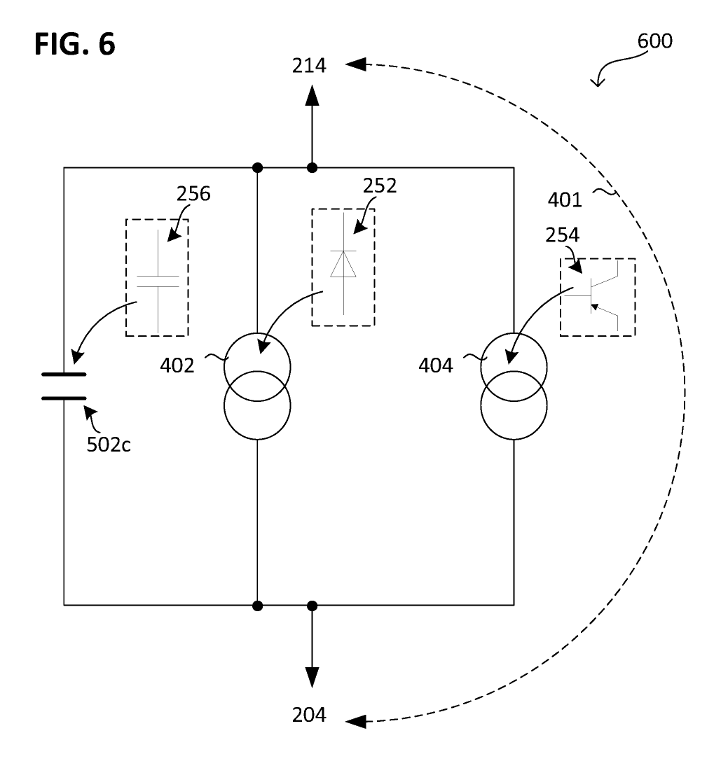

FIG. 6 illustrates a second electrical network 600 in a schematic circuit diagram according to various embodiments, similar to the second electrical networks described before.

The second electrical network 600 may include a capacitor 502c (e.g. Crr) coupled in parallel to the first current source 402 and the second current source 404. The capacitor 502c may represent the third parasitic element 256, e.g. a parasitic capacitance of the transistor, e.g. of the first parasitic element 252.

The first current source 402 may represent the first parasitic element 252, e.g. the parasitic diode of the transistor. The second current source 404 may represent the second parasitic element 254 of the transistor, e.g. the bipolar-element 254.

The first current source 402 and the second current source 404 may be configured to generate a current depending on the first parameter 401.

FIG. 7 illustrates a second electrical network 700 in a schematic circuit diagram according to various embodiments, similar to the second electrical networks described before.

The second electrical network 700 may include a first resistor 502r (also referred to as R_capacitor) coupled in parallel to the first current source 402 and the second current source 404 and serially to the capacitor 502c. The first resistor 502r and the capacitor may form a first RC-component 502c, 502r (also referred to as RC-filter or RC-network). The first RC-component 502c, 502r may represent a dissipation characteristic of the third parasitic element 256, e.g. the parasitic capacitance. For example, the first RC-component 502c, 502r may represent an energy dissipation of the third parasitic element 256.

FIG. 8 illustrates a second electrical network 800 in a schematic circuit diagram according to various embodiments, similar to the second electrical networks described before.

According to various embodiments, the second electrical network 800 may include a controlled third electrical energy source 406 (also referred to as third source 406), e.g. a controlled first voltage source 406, coupled serially to the capacitor 502c and in parallel to the first current source 402 and the second current source 404. The third electrical energy source 406 may be configured to generate a voltage in accordance with the charging characteristic of the third parasitic element 256, e.g. the parasitic capacitance.

The charging characteristic may be defined by a time dependency of charging the third parasitic element 256, e.g. the time dependent charge flow or time dependent current flow generated and/or absorbed by the third parasitic element 256. Alternatively or additionally, the charging characteristic may represent an operation mode dependency of charging the third parasitic element 256, e.g. in dependency of the polarity between the source node 204 and the drain node 214. By way of example, the charging characteristic may illustratively define how fast and how much the third parasitic element 256 is charged or discharged. The charging characteristic may be configured to charge the capacitor 502c in the forward operation slower than in the reverse operation. In other words, the charging characteristic may be configured to transfer in the forward operation less charge to the capacitor 502c than in the reverse operation.

The controlled third electrical energy source 406 and the capacitor 502c may form a controlled capacitance component 502 (e.g. controlled in dependency on the operation mode and alternatively or additionally controlled in dependency on the first parameter). Optionally, the controlled capacitance component 502 may include the first resistor 502r coupled in parallel to the first current source 402 and the second current source 404 and serially to the capacitor 502c.

The third electrical energy source 406 may be controlled by the first parameter 401. The third electrical energy source 406 (exemplarily in the following first voltage source 406) may be configured to generate a voltage in dependency of the first parameter 401, e.g. in accordance with the charging characteristic.

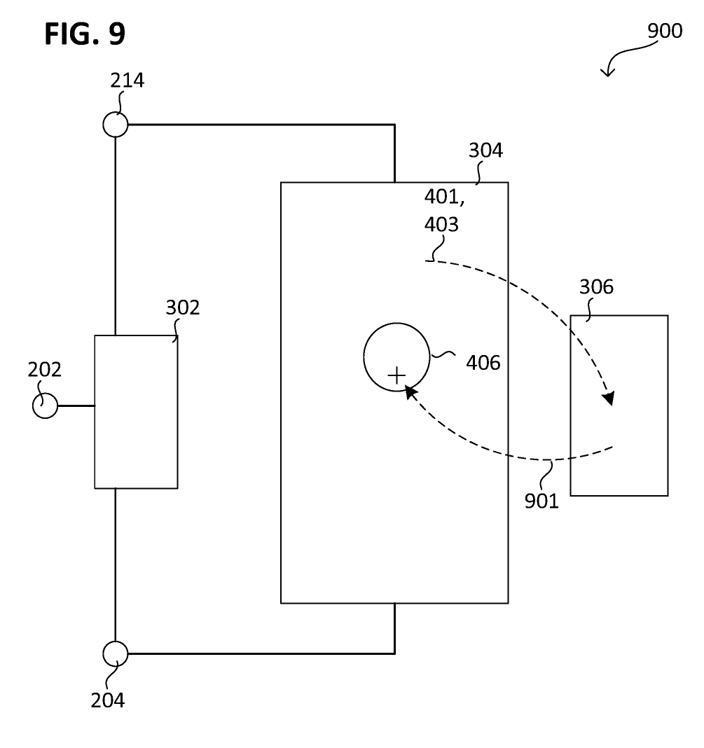

FIG. 9 illustrates a transistor model 900 in a schematic circuit diagram according to various embodiments.

According to various embodiments, the transistor model 900 may include the first electrical network 302. The transistor model 900 may include a second electrical network 304, e.g. similar to the second electrical networks described before.

The transistor model 900 may further include a third electrical network 306. The third electrical network 306 may be configured provide a third parameter 901 based on at least one further parameter, e.g. on at least one of the first parameter 401 and the second parameter 403. The at least one further parameter and the third parameter 901 may differ in at least one of a time dependency and an operation mode of the transistor. Illustratively, the third parameter 901 may consider a charging polarity dependent characteristic of the parasitic capacitance. The further parameter may be a parameter of the first electrical characteristic (in other words, the second parameter 403), e.g. a current generated by the first current source 402. The third electrical network 306 may provide the third parameter 901 in accordance with an electrical characteristic of the third electrical network 306 (also referred to as operation mode characteristic). The operation mode characteristic may correlate the at least one further parameter 401, 403 and the third parameter 901.

The third electrical energy source 406 may be controlled by the third parameter 901 provided by the third electrical network 306. The third electrical energy source 406 (exemplarily in the following first voltage source 406) may be configured to generate a voltage in dependency of the third parameter 901 (also referred to as third controlling parameter 901), e.g. in accordance with the charging characteristic. The third parameter 901 may represent (e.g. be identical or a function of) an electrical parameter. By way of example, the third parameter 901 may represent (e.g. be identical or a function of) at least one of voltage and a current of the third electrical network 306.

The third electrical network 306 may be configured generate the third parameter 901 based on the first parameter 401. In this context, the third parameter 901 may represent (e.g. be identical or a function of) the same as the first parameter 401, e.g. a voltage between the source node 204 and the drain node 214. For example, the third electrical network 306 may be configured to generate the third parameter 901 based on the voltage between the source node 204 and the drain node 214.

For example, the first parameter 401 may be an electric voltage between the source node 204 and the drain node 214 (illustratively, the drain-source voltage). Alternatively or additionally, the first parameter 401 may include the polarity between the source node 204 and the drain node 214. Using the voltage between the source node 204 and the drain node 214 may avoid additional interference during discharging the parasitic capacitance of the transistor, e.g., induced decreasing the voltage over the parasitic capacitance, e.g., from 400 V to 100 V. This may enable to activate the controlled sources beyond (e.g., before or after) the diode operation mode.

For example, third electrical network 306 may sense the operation mode of the transistor (illustratively, whether the transistor is in a forward operation, commutation operation and/or in a reverse operation), e.g. via at least one of the first parameter 401 and the second parameter. The third electrical network 306 may be configured to control the first voltage source 406 depending on the sensed operation mode. For example, the third electrical network 306 may sense a polarity between the source node 204 and the drain node 214. Illustratively, the third electrical network 306 may be configured to control 901 the third electrical energy source 406 based on an operation mode of the transistor, e.g. the field effect transistor.

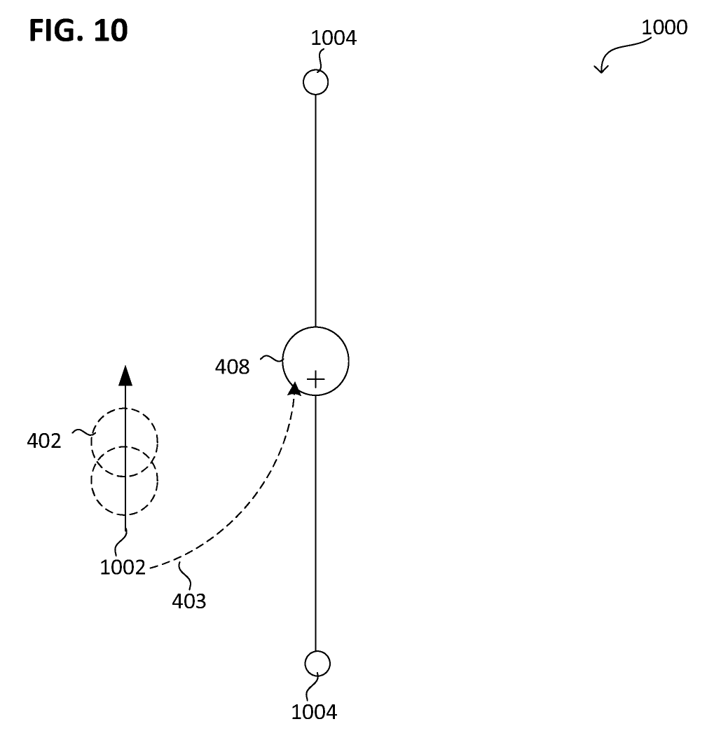

FIG. 10 illustrates a third electrical network 1000 in a schematic circuit diagram according to various embodiments, similar to the second electrical networks described before.

According to various embodiments, the third electrical network 1000 may include a fourth electrical energy source 408 (also referred to as fourth source 408), e.g. a second voltage source 408 (also referred to as E_a). The fourth electrical energy source 408 may be coupled between two nodes 1004.

According to various embodiments, the fourth electrical energy source 408 may be controlled by the second parameter 403, e.g. representing an output 403 of the first electrical energy source 402. Illustratively, the output 403 of the first electrical energy source 402 may define the second parameter 403, e.g. representing or being the current 1002 generated by the first current source 402.

The fourth electrical energy source 406 (exemplarily second voltage source 408 in the following) may be configured to generate a voltage depending the second parameter 403 (also referred to as second controlling parameter 403), e.g. on a current generated by the first current source 402. If the first current source 402 is configured to generate a current depending on the first parameter 401, the second parameter 403 may represent (e.g. be identical or a function of) the same as the first parameter 401, e.g. a voltage between the drain node 214 and the source node 204.

According to various embodiments, the two nodes 1004 may be equipotential. In other words, the two nodes 1004 may having the same potential, e.g. a reference potential, e.g. electrical ground.

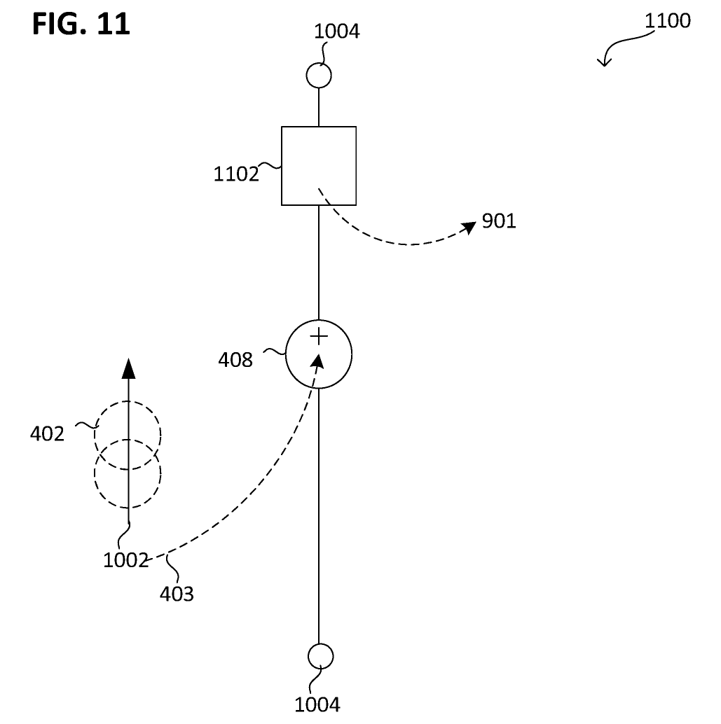

FIG. 11 illustrates a third electrical network 1100 in a schematic circuit diagram according to various embodiments, similar to the second electrical networks described before.

According to various embodiments, the third electrical network 1100 may include an inductance 1102 (e.g., alone or included in a second RC-component 1102). The inductance 1102 (or the respective second RC-component 1102) may represent a time dependency with which the parasitic capacitance is charged and/or discharged. The inductance 1102 (or the respective second RC-component 1102) may configured to provide the third parameter 901, e.g. being or representing a voltage over the inductance 1102 (or of the respective second RC-component 1102).

According to various embodiments, the second RC-component 1102 may include a resistor (also referred to as R_B) and a capacitance (also referred to as C_b).

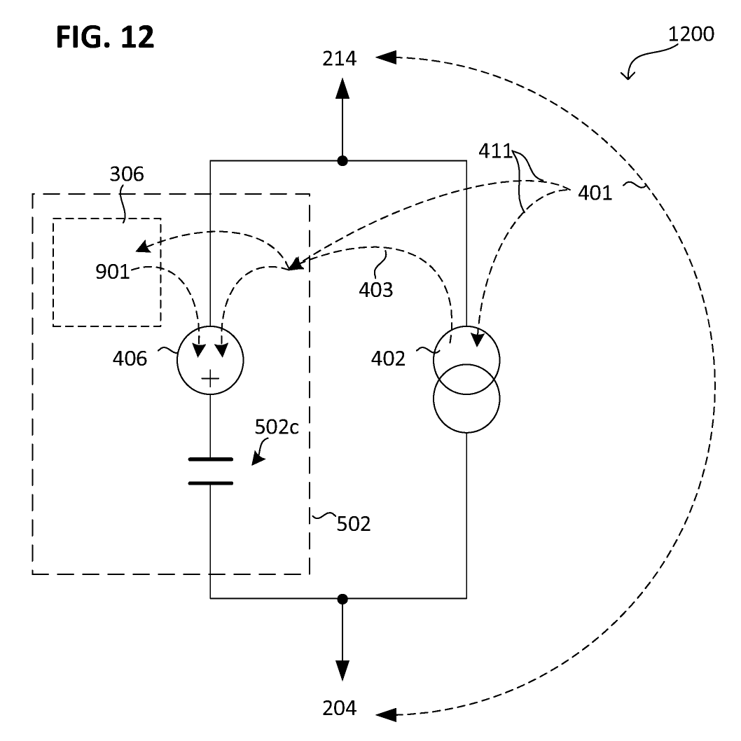

FIG. 12 illustrates a second electrical network 1200 in a schematic circuit diagram according to various embodiments, similar to the second electrical networks described before.

According to various embodiments, the second electrical network 1200 may include the first current source 402 and the controlled capacitance component 502. The controlled capacitance component 502 may include the first voltage source 406.

The controlled capacitance component 502 and the first current source 402 may be controlled by the first parameter 401. The first parameter 401 may represent (e.g. be identical or a function of) at least one of the polarity (direction of the voltage) and the voltage from the source node 204 to the drain node 214.

Alternatively or additionally, the controlled capacitance component 502 may be controlled by the second parameter 403. The second parameter 403 may represent (e.g. be identical or a function of) an output of the first current source 402.

By way of example, the first voltage source 406 may be controlled by at least one of the first parameter 401 and the second parameter 403. Alternatively or additionally, the first voltage source 406 may be controlled by the third parameter 901 converted from at least one of the first parameter 401 and the second parameter 403, e.g. via the third electrical network 306.

Further, the controlled capacitance component 502 may include the capacitor 502c (e.g. Crr) coupled serially to the first voltage source 406. The capacitor 502c may represent a third parasitic element 256 of the transistor, e.g. the parasitic capacitance.

Illustratively, the first voltage source 406 may be configured to provide a controlled charging and/or discharging of the capacitor 502c.

For example, the first voltage source 406 may be configured to generate a voltage depending on a polarity of the first parameter. The first voltage source 406 controlled by the polarity may consider a polarity dependent charging characteristic of the parasitic capacitance. The charging characteristic may represent a time dependency of charging the capacitor 502c, e.g. the time dependent charge flow or time dependent current flow generated and/or absorbed by the capacitor 502c. Alternatively or additionally, the charging characteristic may represent an operation mode dependency of charging the capacitor 502c, e.g. in dependency of the polarity between the source node 204 and the drain node 214.

For example, the charging characteristic may illustratively define how fast and how much the capacitor 502c is charged or discharged. The controlled capacitor component 502 may be configured to charge the capacitor 502c in the forward operation slower than in the reverse operation, e.g. to block a charging in the forward operation.

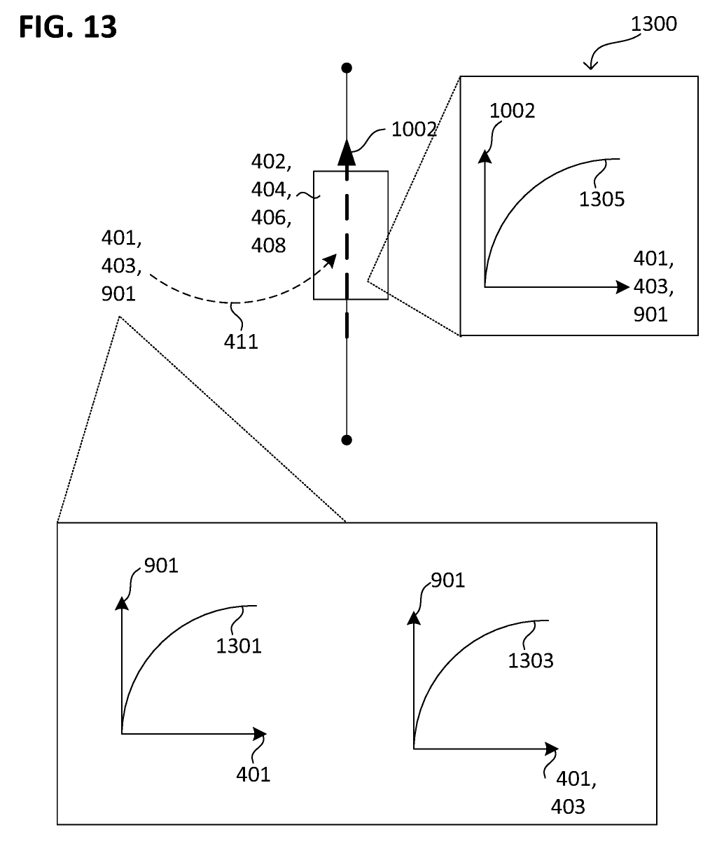

FIG. 13 illustrates an electrical network 1300 in a schematic circuit diagram according to various embodiments, e.g. similar to the second electrical networks described before and/or e.g. similar to the third electrical networks described before.

According to various embodiments, an electrical energy source 402, 404, 406, 408 (e.g. at least one of the first current source 402, the second current source 404, the first voltage source 406 and the second voltage source 408) may be controlled 411 by at least one parameter 401, 901, 403 (e.g. by at least one of the first parameter 401, the third parameter 901 and the second parameter 403). In other words, the output 1002 of the electrical energy source 402, 404, 406, 408 may be controlled by the at least one parameter 401, 901, 403, e.g. in accordance with the electrical characteristic 1305 of the electrical energy source 402, 404, 406, 408.

The at least one parameter 401, 901, 403 may represent a voltage (potential difference) between the source node 204 and the drain node 214.

Optionally, the at least one parameter 401, 901, 403 include two correlated parameters. For example, the first parameter 401 may be converted into the second parameter 403.

For example, the second parameter 403 may represent (e.g. be identical or a function of) an output of the first electrical energy source 402 (which may be controlled by the first parameter 401). In this context, the second parameter 403 may be provided (illustratively, converted from the first parameter 401) in accordance with the electric characteristic 1301 of the first electrical energy source 402 (e.g. a unipolar-junction characteristic). Illustratively, the electric characteristic 1301 of the first electrical energy source 402 may define the correlation of the second parameter 403 and the first parameter 401.

For example, the third parameter 901 may be provided by the third electrical network 306 (which may be controlled by the first parameter 401 or the second parameter 403). In this context, at least one of the first parameter 401 and the second parameter 403 may be converted in accordance with the electric characteristic 1303 of the third electrical network 306 (operation mode characteristic). Illustratively, the electric characteristic 1303 of the third electrical network 306 may define the correlation of the third parameter 901 and at least one of the first parameter 401 and the second parameter 403.

According to various embodiments, the at least one parameter 401, 901, 403 may be provided otherwise.

By way of example, the first parameter 401 may include (e.g. include or be formed from) at least one of: a voltage (in other words, a potential difference, illustratively, a voltage drop) over the first current source 402; a voltage over the second current source 404; a polarity between the source node 204 and the drain node 214; and a voltage between the source node 204 and the drain node 214.

By way of example, the second parameter 403 may include (e.g. include or be formed from) at least one of: an output of (e.g. a current generated by) the first current source 402; an output of (e.g. a current generated by) the second current source 404, a voltage over the first current source 402; and a voltage over the second current source 404.

By way of example, the third parameter 901 may include (e.g. include or be formed from) at least one of: a voltage generated by the second voltage source 408; a voltage over the second RC-component; and a voltage between the resistor and the capacitor of the RC-component.

A current source 402, 404 may be configured to generate a current 1002 depending on the at least one parameter 401, 403, 901. For example, the first current source 404 may be configured to generate a current 1002 (e.g. provided as second parameter 403) depending on a voltage 401 over the first current source 402, e.g. in accordance with a unipolar junction characteristic. In other words, the first current source 404 may be voltage controlled, e.g. in accordance with the unipolar junction characteristic. For example, the second current source 404 may be configured to generate a current 1002 depending on the second parameter 403 (e.g. the current 403 generated by the first current source 402), e.g. in accordance with a bipolar-junction characteristic. In other words, the second current source 404 may be current controlled, e.g. in accordance with the bipolar-junction characteristic. The bipolar-junction may be also referred to as integrated bipolar-junction.

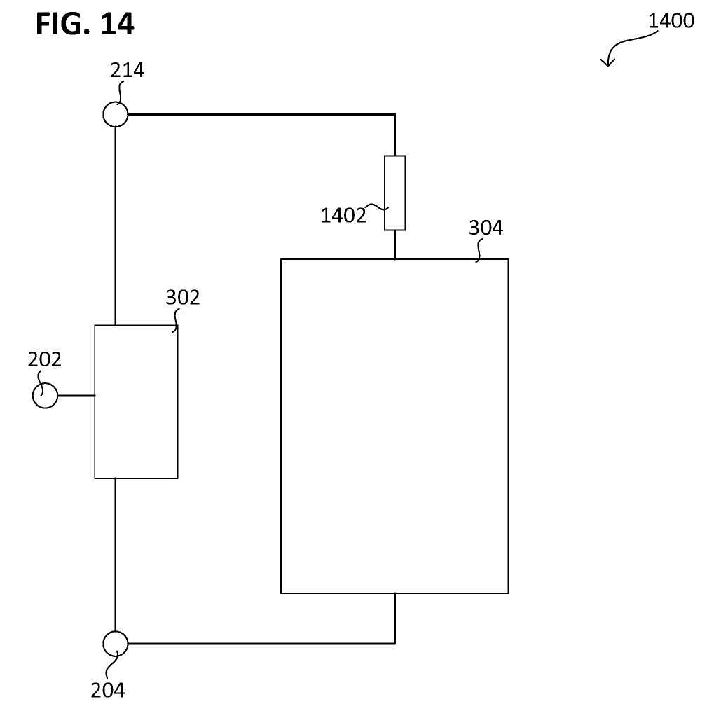

FIG. 14 illustrates a transistor model 1400 in a schematic circuit diagram according to various embodiments, e.g. similar to the previous described transistor models.

The transistor model 1400 may include a second resistor 1402 (also referred to as R_Socket) coupled between the drain node 214 and the second electrical network 304 (e.g. one of the previous described second electrical networks). The second resistor 1402 may represent a cross sectional chip area of the transistor, e.g. the field effect transistor.

According to various embodiments, the chip area may include or be formed from an active area of the transistor and a rim area of the transistor (e.g., a super-junction MOSFET). The rim area may substantially surround the active area. Illustratively, the chip area may represent a size of the chip. For example, in the active area, the transistor may be formed as illustrated in FIG. 2. Through the active area, the transistor may be activated (increased source-drain conductivity) or deactivated (decreased source-drain conductivity) by applying a gate-source voltage. In contrast thereto, in the rim area, the conductivity of the transistor may be substantially independent from the gate-source voltage. However, in the diode operation mode, a current may flow through the rim area (also referred to as rim current). For example, the rim area may include or be formed from at least one unipolar junction (e.g., formed as pn-column), e.g., to provide a depletion zone having a blocking voltage. The at least one unipolar junction of the rim area may be electrically conductive in the diode operation mode, which may result in the rim current. Therefore, the chip area may consider the total current through the transistor including the rim current. Alternatively or additionally, in forward operation mode, the current may be limited by flowing through the active area.

The cross sectional chip area may be understood as describing an area of a cross section (cross sectional area) of the transistor, wherein the cross section is perpendicular to a current directing from the drain node 214 to the source node 204 or vice versa. The chip area of the transistor may be a cross sectional area of at least one of the drain contact 114 and the fifth doped region 116, e.g. an interface area of the drain contact 114 and the fifth doped region 116 (see FIG. 1).

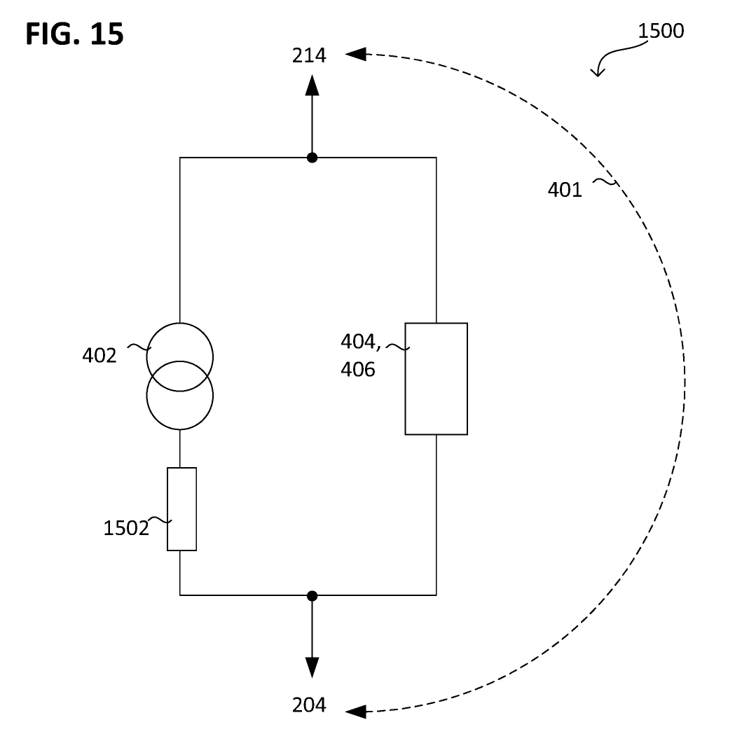

FIG. 15 illustrates a second electrical network 1500 in a schematic circuit diagram according to various embodiments, similar to the second electrical networks described before.

The second electrical network 1500 may include a third resistor 1502 (also referred to as R_pillar) coupled between the source node 204 and the first current source 402 and in parallel to a further electrical energy source 404, 406 of the second electrical network 1500, e.g. to at least one of the second current source 404 and the first voltage source 406. The third resistor 1502 may represent a track resistance of the transistor. The track resistance may be understood as resistance of the transistor between the source contact 104 and the unipolar-junction (e.g. pn-junction or np-junction). The track resistance may be defined by a cross sectional area of the second doped region 108.

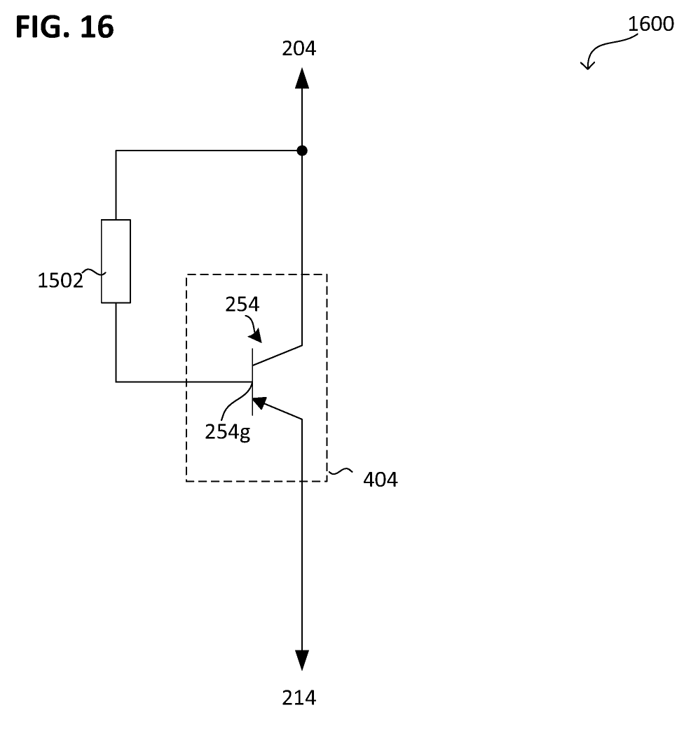

FIG. 16 illustrates a second electrical network 1600 in a schematic circuit diagram according to various embodiments, similar to the second electrical networks described before.

According to various embodiments, the third resistor 1502 may be coupled to the gate 254g of the parasitic bipolar-junction 254, e.g. between the source node 204 and the gate 254g.

Illustratively, the second electrical energy source 404 may be controlled by a current through the third resistor 1502 (e.g. provided as second parameter 403). The current through the resistor 1502 may be defined by the current generated by the first current source 402.

In this context, a resistance of the parasitic bipolar-junction 254 may be controlled by a current through the third resistor 1502 (representing the track resistance). This may consider that a current through parasitic unipolar junction defines the resistance of the parasitic bipolar-junction 254.

The resistance of the parasitic bipolar-junction 254 may be understood as electric characteristic defining the current through the parasitic bipolar-junction 254 (between source node 204 and drain node 214) and the voltage over the parasitic bipolar-junction 254 parallel thereto.

The correlation of the resistance of the parasitic bipolar-junction 254 and the current through the unipolar junction 252 may be in considered via the electric characteristic of the second electrical energy source 404. In other words, the electric characteristic of the second electrical energy source 404 may represent the correlation of the resistance of the parasitic bipolar-junction 254 and the current through the unipolar-junction 252. For example, the current generated by the second electrical energy source 404 may be a function of at least one of the first parameter 401 and the second parameter 403. This may consider a coupling of the bipolar-junction 254 and the unipolar junction 252.

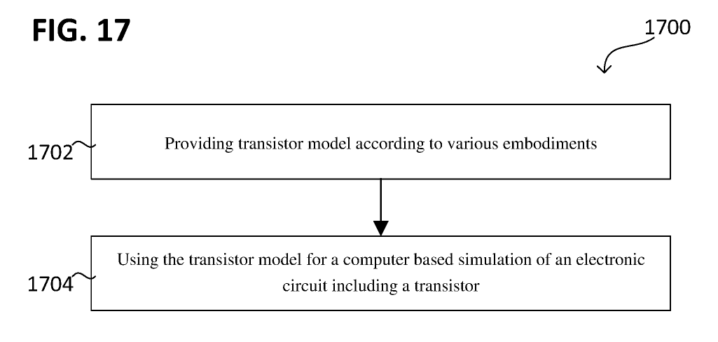

FIG. 17 illustrates a method 1700 in a schematic flow diagram according to various embodiments.

The method 1700 may include in 1702: Providing transistor model according to various embodiments.

The method 1700 may include in 1704: Using the transistor model for a computer based simulation of an electronic circuit including a transistor.

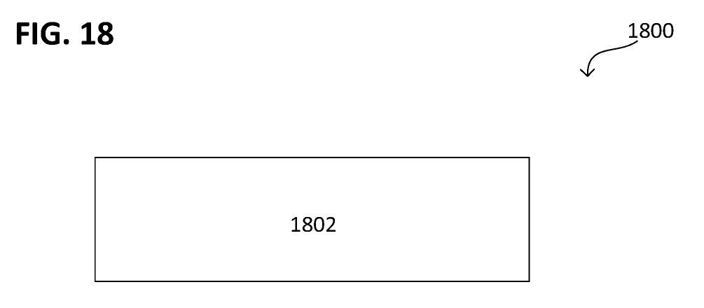

FIG. 18 illustrates computer readable storage medium 1800 in a schematic view according to various embodiments.

The computer readable storage medium 1800 may include code segments 1802 to be executed by a computer.

The computer readable storage medium may be an electronic semiconductor storage medium, e.g. a read only memory (ROM) or a random access memory (RAM), e.g. a (M, S, D, F)—RAM or a (P, E, EE, Flash-EE)—ROM storage medium), a memory card, a Flash-memory, a universal serial bus (USB)-Stick, a solid state drive (SSD), a hard disc drive (HDD), a memory disc (MD), a exchangeable storage medium, a holographic storage medium, an optical storage medium, a compact-disc (CD), a digital-versatile-disc (DCV), a magneto-optical disk or another storage medium.

The code segments 1802 may represent a transistor model according to various embodiments. Alternatively or additionally, the code segments 1802 may represent a database including at least one parameter set representing a transistor (e.g. a field effect transistor). The database may be configured to set up a transistor model according to various embodiments.

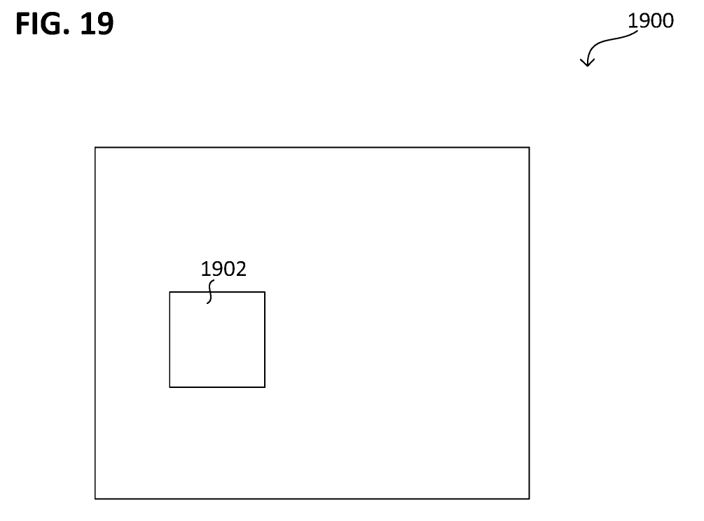

FIG. 19 illustrates a device 1900 in a schematic view according to various embodiments.

The device 1900 may include a processor 1902 configured to simulate a transistor based on a transistor model according to various embodiments.

For example, the processor 1902 may execute the code segments 1802, e.g. stored on the computer readable storage medium 1900, e.g. via a bus system of the device 1900. For example, the processor 1902 may process the transistor model. Optionally, the processor 1902 may be configured to set up the transistor model using the database. Alternatively or additionally, the processor 1902 may be configured generate or modify the database according to results of the transistor model.

The processor 1902 may be configured for computing operations. For example, the processor 1902 may include or be formed from a microchip, e.g. an integrated microchip. For example, the processor 1902 may include or be formed from a CPU (Central Processing Unit) or a GPU (Graphic Processing Unit). The processor 1902 may be a multi-core processor. The processor may be connected to a bus system of the device 1900.

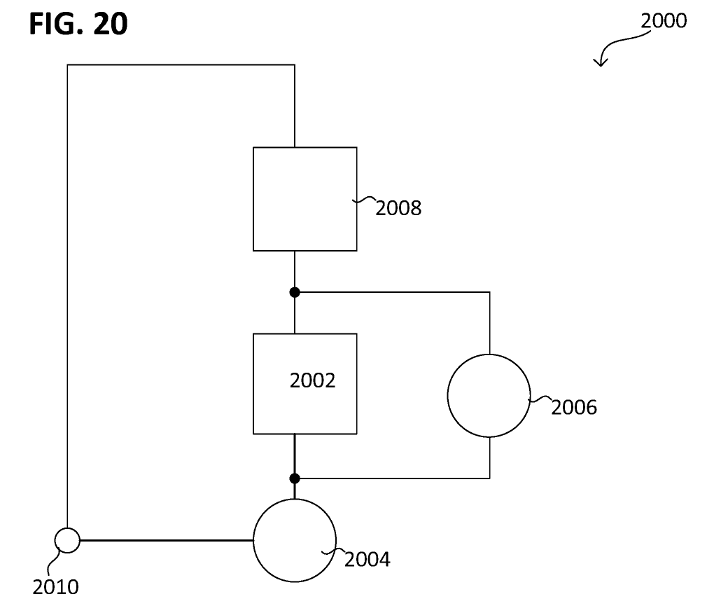

FIG. 20 illustrates a commutation circuit model 2000 in a schematic circuit diagram according to various embodiments.

The commutation circuit model 2000 may include a transistor model 2002 according to various embodiments. The commutation circuit model 2000 may further include a reference node 2010. The reference node 2010 may define a reference potential, e.g. electrical ground.

The commutation circuit model 2000 may further include a first sensor 2004 coupled between the transistor model 2002 and the reference node 2010. The first sensor 2004 may be configured to sense an electrical current, e.g. through the sensor 2004.

The commutation circuit model 2000 may further include a signal generator 2008. The signal generator 2008 may be configured to generate an electrical signal (also referred to as test signal), e.g. a current and/or a voltage. The electrical signal may be supported to the transistor model 2002.

The commutation circuit model 2000 may further include a second sensor 2006 coupled parallel to the transistor model 2002, e.g. between the signal generator 2008 and the first sensor 2004. The second sensor 2006 may be configured to sense an electrical voltage, e.g. over the transistor model 2002.

The electrical characteristic of the transistor model 2002 may be derived from the output of the first sensor 2004 and the second sensor 2006.

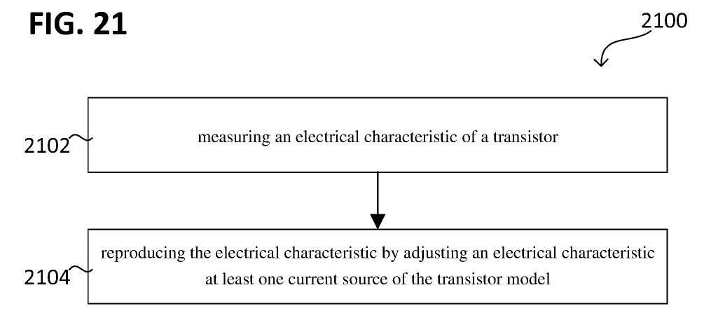

FIG. 21 illustrates a method 2100 in a schematic flow diagram according to various embodiments.

The method may include in 2102: measuring an electrical characteristic of a transistor, e.g. a field effect transistor.

The method may include in 2104: reproducing the electrical characteristic using a transistor model according to various embodiments by adjusting an electrical characteristic of the transistor model.

Reproducing the electrical characteristic may include or be formed from setting up the transistor model using at least one at least one parameter and/or at least one electrical characteristic, e.g. by loading them from a database.

Adjusting the electrical characteristic of the transistor model may include modifying at least one parameter and/or at least one electrical characteristic used in the transistor model.

Adjusting the electrical characteristic may include reducing a deviation of the transistor model from the transistor, e.g. in their electric characteristics.

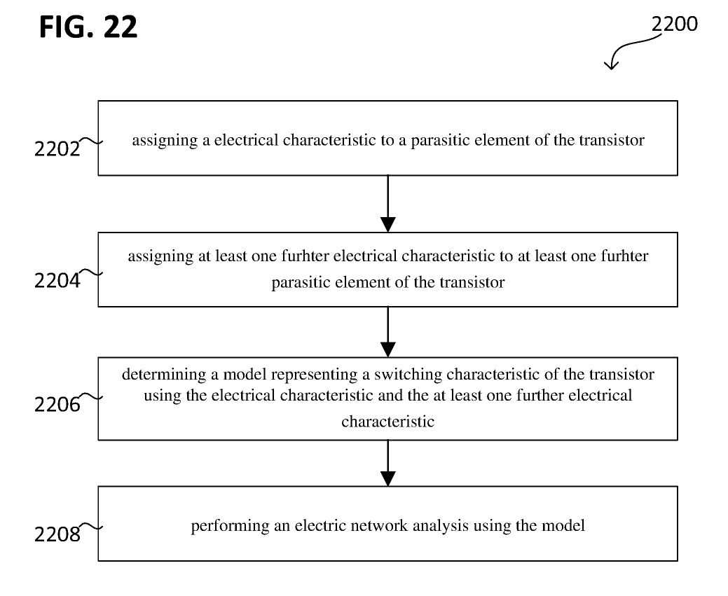

FIG. 22 illustrates a method 2200 in a schematic flow diagram according to various embodiments.

The method may include in 2202: assigning an electrical characteristic to a parasitic element (e.g. for modeling a unipolar-junction, e.g. a diode) of the transistor.

The method may include in 2204: assigning at least one further electrical characteristic to at least one further parasitic element (also referred to as parasitic impedance of the transistor), e.g. at least one of the second parasitic element (e.g. for modeling a bipolar-junction, e.g. an npn-junction or a pnp-junction, of the transistor) and the third parasitic element (e.g. for modeling a capacitance of the parasitic element).

The method may include in 2206: determining a model (transistor model) representing an electrical characteristic (e.g. a switching characteristic) of the transistor using the electrical characteristic and the at least one further electrical characteristic.

The method may optionally include coupling the electrical characteristic with the at least one further electrical characteristic, e.g. via the at least one parameter.

The method may include in 2208: performing an electric network analysis using the model.

According to various embodiments, the model may represent a parallel connection of the parasitic element and the at least one further parasitic element.

According to various embodiments, both, the electrical characteristic and the at least one further electrical characteristic may be coupled to each other by at least one parameter. The at least one parameter may represent an electrical voltage over the transistor. The method may consider a coupling between the parasitic element and the at least one further parasitic element (e.g. at least one of the parasitic capacitance and the bipolar-junction).

The electrical characteristic and the at least one further electrical characteristic may each define a correlation of two electrical parameters, e.g. an electrical voltage and an electrical current or a first electrical voltage and a second electrical voltage. The electrical characteristic and the at least one further electrical characteristic may be coupled to each other, e.g. via the at least one parameter (e.g. via at least the second parameter 403). Optionally, the electrical characteristic and the at least one further electrical characteristic may share at least one parameter, e.g. the second parameter 403. The electrical characteristic may include or be formed from the first electrical characteristic. The at least one further electrical characteristic may include or be formed from at least one of: the second electrical characteristic and the third electrical characteristic (in other words, the second electrical characteristic and/or the third electrical characteristic).

According to various embodiments, the first electrical characteristic may represent a unipolar-junction, e.g. a diode. For example, the first electrical characteristic may be an electrical unipolar junction characteristic.

According to various embodiments, the at least one further electrical characteristic (e.g. the second electrical characteristic) may represent a bipolar—junction, e.g. a parasitic npn-structure and/or parasitic pnp-structure (e.g., a parasitic bipolar transistor). For example, the at least one further electrical characteristic (e.g. the second electrical characteristic) may include or be formed from an electrical bipolar characteristic. Alternatively or additionally, the at least one further electrical characteristic (e.g. the third electrical characteristic) may represent a charge storage capacity of the first parasitic element. For example, the at least one further electrical characteristic (e.g. the second electrical characteristic) may include or be formed from a charging characteristic (e.g. of Crr) of the first parasitic element.

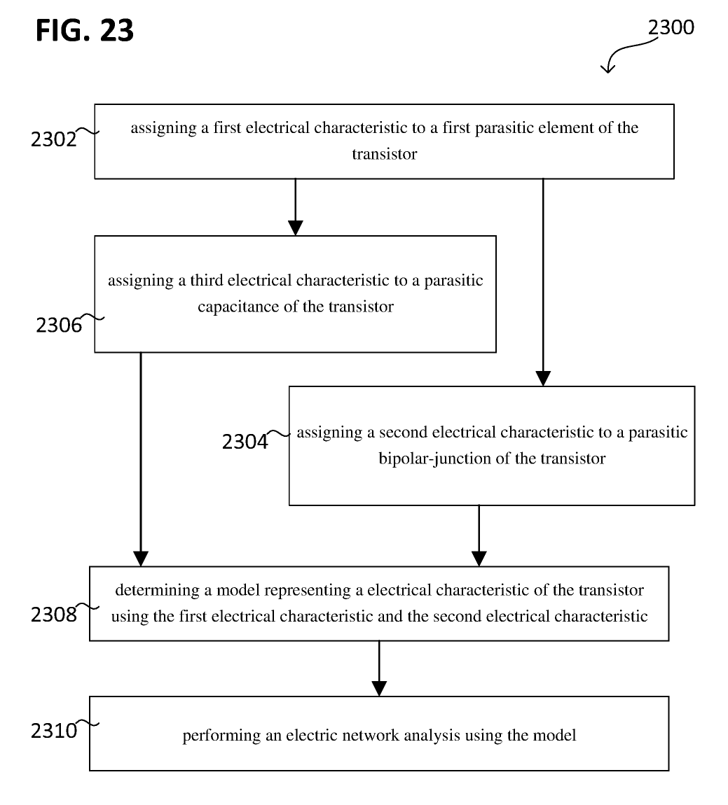

FIG. 23 illustrates a method 2300 in a schematic flow diagram according to various embodiments.

The method 2300 may include the method 2302 assigning a first electrical characteristic to a first parasitic element of the transistor, e.g. to a unipolar-junction of the transistor.

The method 2300 may further include in 2304: assigning a second electrical characteristic to a parasitic bipolar-junction of the transistor, e.g. a bipolar-junction characteristic. The model may represent a parallel connection of the parasitic bipolar-junction to the first parasitic element and to the second parasitic element.

The method 2300 may alternatively include in 2306: assigning a third electrical characteristic (e.g. of Crr) to a parasitic capacitance of the transistor, e.g. a charging characteristic of the first parasitic element. The model may represent a parallel connection of the parasitic capacitance to the first parasitic element and to the second parasitic element.

The method 2300 may further include in 2308: determining a model representing an electrical characteristic of the transistor using the first electrical characteristic and the second electrical characteristic.

The method may optionally include coupling the first electrical characteristic with at least one of the second electrical characteristic and the third electrical characteristic, e.g. via the at least one parameter.

The method 2300 may further include in 2310: performing an electric network analysis using the model.

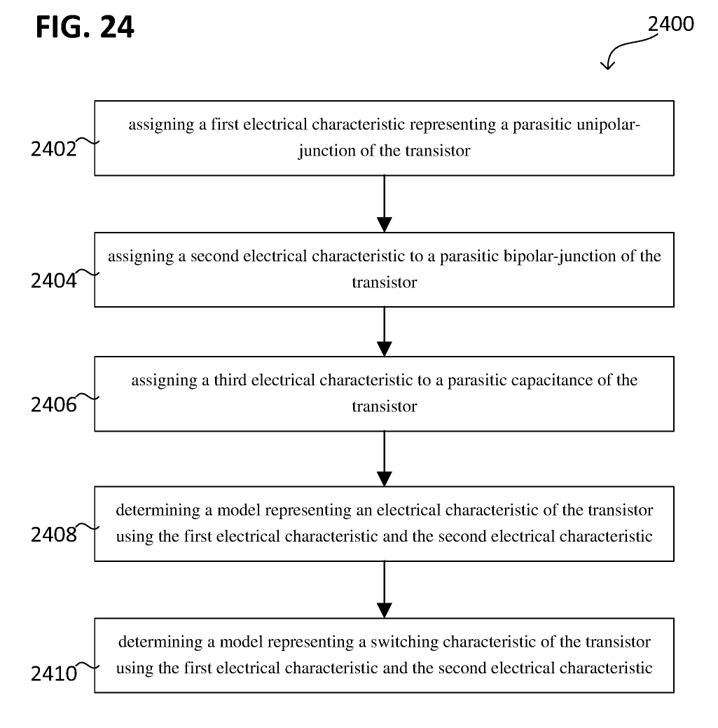

FIG. 24 illustrates a method 2400 in a schematic flow diagram according to various embodiments.

The method may include in 2402: assigning a first electrical characteristic representing a parasitic unipolar-junction of the transistor (e.g. to a parasitic diode of the transistor).

The method may include in 2404: assigning a second electrical characteristic to a parasitic bipolar-junction (e.g. to a parasitic bipolar-transistor of the transistor).

The method may include in 2406: assigning a third electrical characteristic to a parasitic capacitance of the transistor (e.g. to a parasitic capacitance of the unipolar-junction).

The method may include in 2408: determining a model representing electrical network electrical characteristic (e.g. a switching characteristic) of the transistor using the first electrical characteristic, the second electrical characteristic and the third electrical characteristic.

According to various embodiments, the model may represent a parallel connection of the first electrical characteristic, the second electrical characteristic and the third electrical characteristic.

The method may optionally include: Coupling the first electrical characteristic and the second electrical characteristic by at least one parameter. In other words, the method may consider a coupling between the parasitic unipolar-junction and the parasitic bipolar-junction.

The method may optionally include: Coupling the first electrical characteristic and the third electrical characteristic by the at least one parameter. In other words, the method may consider a coupling between the parasitic unipolar-junction and the parasitic capacitance.

The method may include in 2410: performing an electric network analysis using the model.

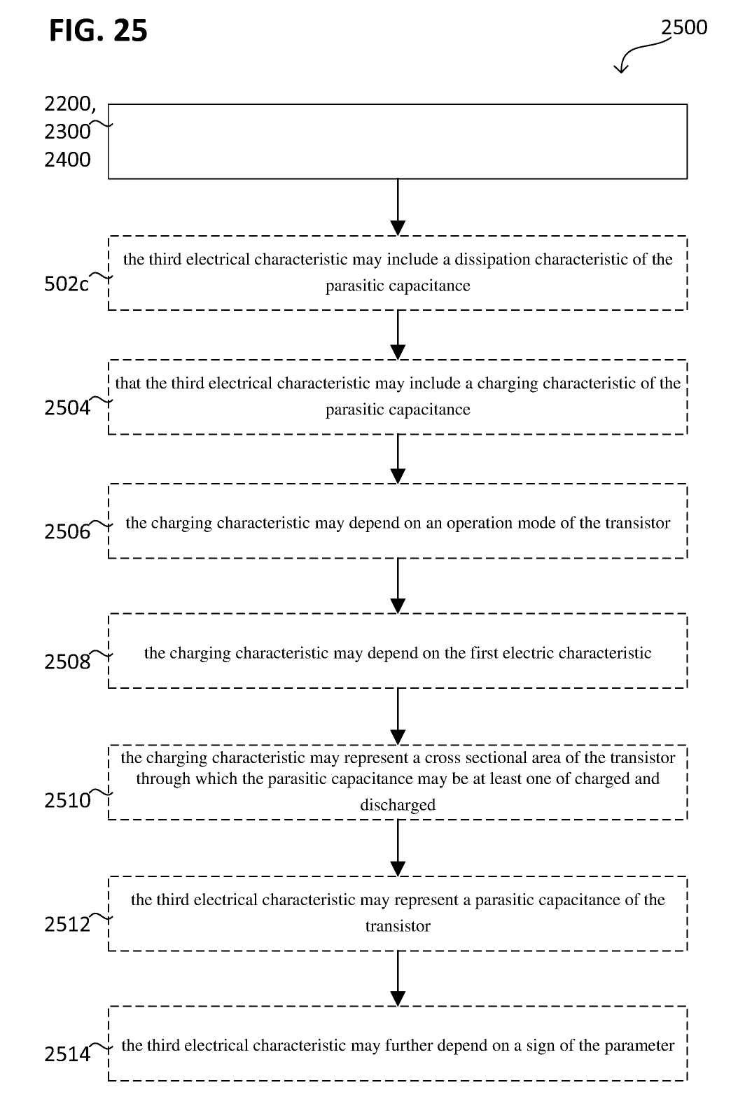

FIG. 25 illustrates a method 2500 in a schematic flow diagram according to various embodiments.

The method 2500 may include the method 2200, 2300 or 2400.

The method 2500 may optionally include in 2502 that the third electrical characteristic may include a dissipation characteristic of the parasitic capacitance.

The method 2500 may optionally include in 2504 that the third electrical characteristic may include or be formed from a charging characteristic of the parasitic capacitance (e.g. a time and/or operation mode dependency of charging the parasitic capacitance).

The method 2500 may optionally include in 2506 that the charging characteristic may depend on an operation mode of the transistor.

The method 2500 may optionally include in 2508 that the charging characteristic may depend on the first electric characteristic.

The method 2500 may optionally include in 2510 that the charging characteristic may represent a cross sectional area of the transistor through which the parasitic capacitance may be at least one of charged and discharged (in other words, charged and/or discharged).

The method 2500 may optionally include in 2512 that the third electrical characteristic (e.g. of Crr) may represent a parasitic capacitance of the transistor.

The method 2500 may optionally include in 2514 that the third electrical characteristic may further depend on a sign of the parameter.

The third electrical characteristic may be configured to provide a greater charge storage capability in reverse operation than in forward operation. By way of example, the charge storage capability in forward operation may be substantially zero.

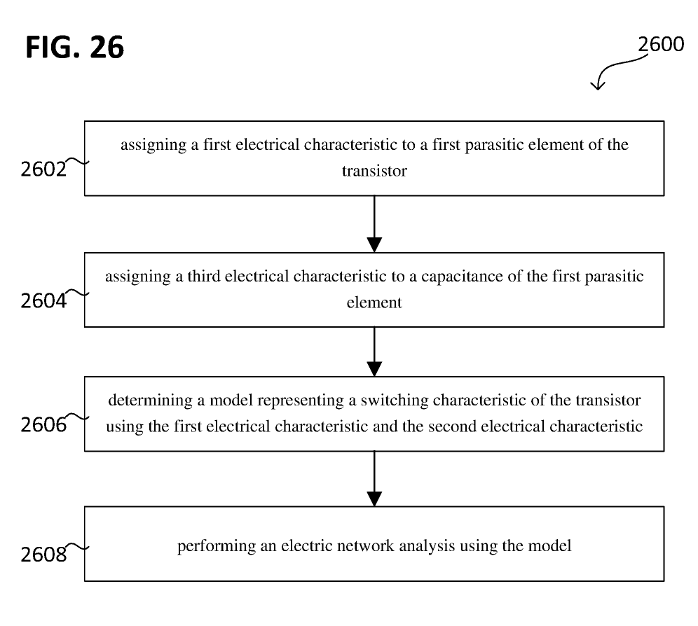

FIG. 26 illustrates a method 2600 in a schematic flow diagram according to various embodiments.

The method 2600 may include in 2602: assigning a first electrical characteristic to a first parasitic element (e.g. a parasitic junction of the transistor, e.g. a unipolar-junction or bipolar-junction) of the transistor.

The method 2600 may further include in 2604: assigning a third electrical characteristic to a capacitance of the first parasitic element of the transistor.

The method may optionally include: Coupling the third electrical characteristic to the first electrical characteristic by at least one parameter.

The method 2600 may further include in 2606: determining a model representing an electrical characteristic (e.g. a switching characteristic) of the transistor using the first electrical characteristic and the second electrical characteristic.

According to various embodiments, the model may represent a parallel connection of the first parasitic element and the capacitance. Further, both, the first electrical characteristic and the third electrical characteristic, may be at least one of correlated by and depend on the same parameter. The method 2600 may consider a coupling between the first parasitic element and the second parasitic element.

The method 2600 may further include in 2608: performing an electric network analysis using the model.

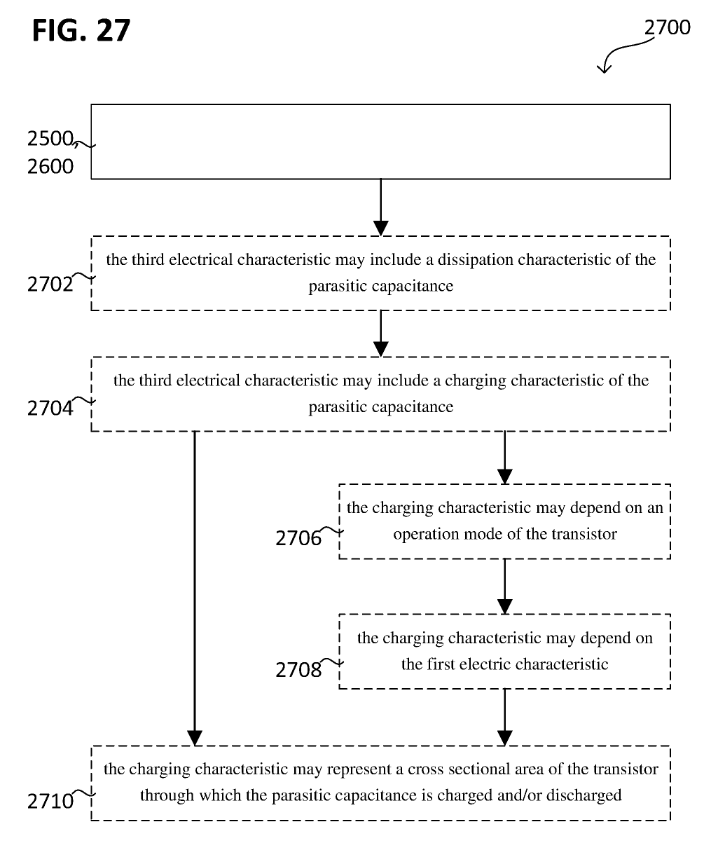

FIG. 27 illustrates a method 2700 in a schematic flow diagram according to various embodiments.

The method 2700 may include the method 2500 or the method 2600.

The method 2700 may optionally include in 2702 that the third electrical characteristic may include a dissipation characteristic of the parasitic capacitance (capacitance of the parasitic element).

The method 2700 may optionally include in 2704 that the third electrical characteristic may include a charging characteristic of the parasitic capacitance (e.g. a time and operation mode dependency of charging the capacitor).

The method 2700 may optionally include in 2706 that the charging characteristic may depend on an operation mode of the transistor.

The method 2700 may optionally include in 2708 that the charging characteristic may depend on the first electric characteristic.

The method 2700 may optionally include in 2710 that the charging characteristic may represent a cross sectional area of the transistor through which the parasitic capacitance is charged and/or discharged.

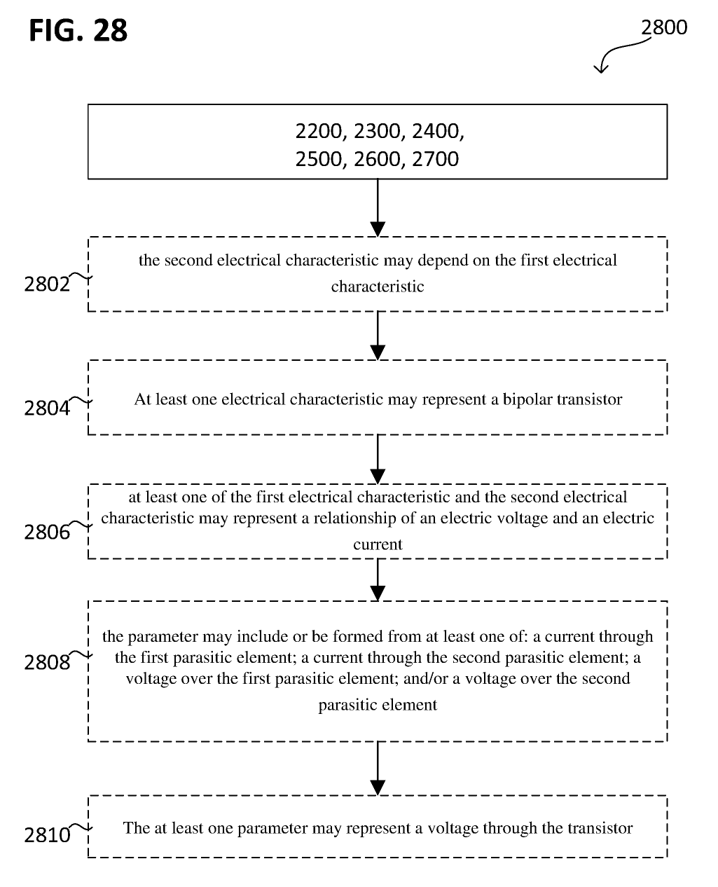

FIG. 28 illustrates a method 2800 in a schematic flow diagram according to various embodiments.

The method 2800 may include any of the methods described before, e.g. any of the methods 2200, 2300, 2400, 2500, 2600, 2700.

The method 2800 may optionally include in 2802 that the second electrical characteristic may depend on the first electrical characteristic, e.g. on a parameter of the first electrical characteristic. This may enable to consider an interaction between the first parasitic element and the second parasitic element.

The method 2800 may optionally include in 2804 that at least one electrical characteristic may represent a parasitic npn-structure and/or parasitic pnp-structure (e.g., a parasitic bipolar transistor).

The method 2800 may optionally include in 2806 that at least one of the first electrical characteristic and the second electrical characteristic may represent a relationship of an electric voltage and an electric current.

By way of example, the first electrical characteristic may represent a current through the first parasitic element in dependency on a voltage over the first parasitic element. By way of example, the second electrical characteristic may represent a current through the second parasitic element in dependency on a voltage over the second parasitic element and optionally on dependency on the current through the first parasitic. By way of example, the third electrical characteristic may represent a current through the third parasitic element in dependency on a voltage over the third parasitic element and optionally on dependency on the current through the first parasitic. The third electrical characteristic may include or be formed from at least one of the operation mode characteristic and the charging characteristic.

The method 2800 may optionally include in 2808 that the at least one parameter may include or be formed from at least one of: a current through the first parasitic element; a current through the second parasitic element; a voltage over the first parasitic element; and/or a voltage over the second parasitic element.

The method 2800 may optionally include in 2810 that the parameter may represent a voltage through the transistor.

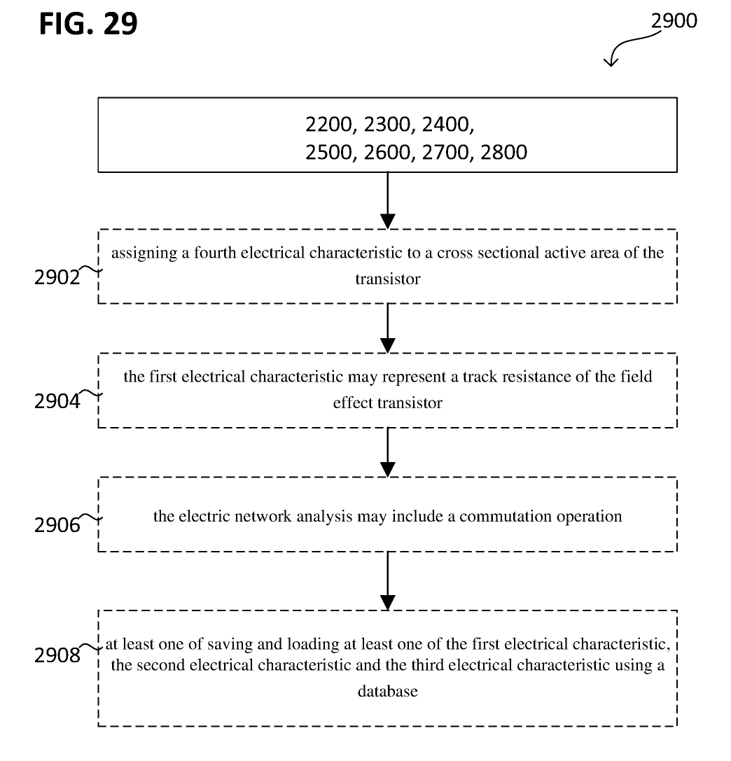

FIG. 29 illustrates a method 2900 in a schematic flow diagram according to various embodiments.

The method 2900 may include any of the methods described before, e.g. any of the methods 2200, 2300, 2400, 2500, 2600, 2700, 2800.

The method 2900 may optionally include in 2902 assigning a fourth electrical characteristic (e.g. a resistive characteristic, e.g. for R_Socket) to a cross sectional chip area of the transistor.

According to various embodiments, the model may represent a serial connection of the cross sectional chip area to at least one of the first parasitic element, the second parasitic element and the third parasitic element.

The method 2900 may optionally include in 2904 that the first electrical characteristic may represent a track resistance (e.g. R_pillar) of the field effect transistor.

The method 2900 may optionally include in 2906 that the electric network analysis may include a commutation operation.

The method 2900 may optionally include in 2906 at least one of saving and loading at least one of the first electrical characteristic, the second electrical characteristic and the third electrical characteristic using a database.

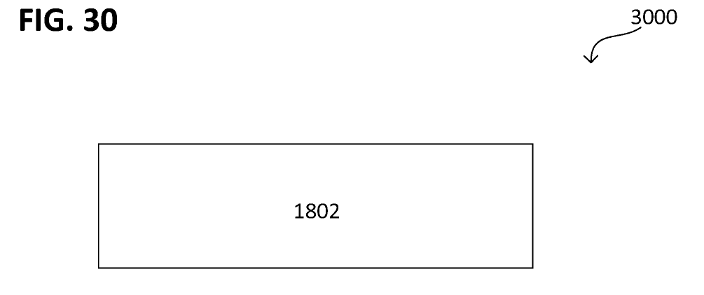

FIG. 30 illustrates (e.g. e.g. non-transitory) computer readable storage medium 3000 in a schematic view according to various embodiments, e.g. similar to the storage medium described before.

The computer readable storage medium 3000 may include code segments 1802 to be executed by a computer.

The code segments 1802 may be configured perform a method according to various embodiments when executed, e.g. any of the methods 2200, 2300, 2400, 2500, 2600, 2700, 2800. Alternatively or additionally, the code segments 1802 may represent a database including at least one parameter set representing a method according to various embodiments, e.g. any of the methods 2200, 2300, 2400, 2500, 2600, 2700, 2800. The database may be configured to set up a method according to various embodiments, e.g. any of the methods 2200, 2300, 2400, 2500, 2600, 2700, 2800.

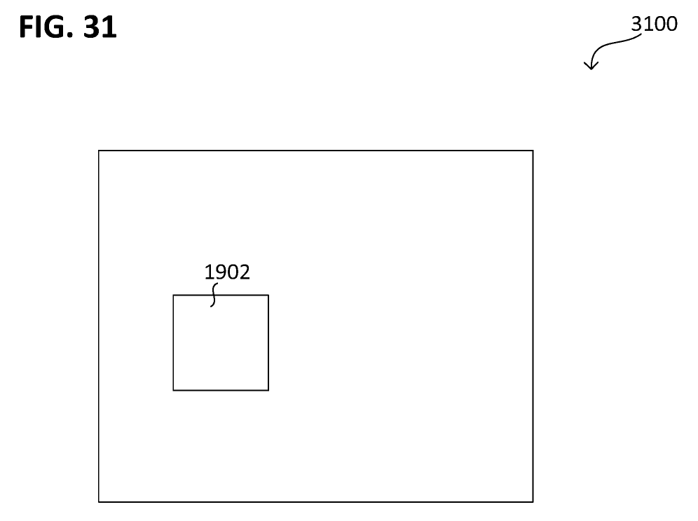

FIG. 31 illustrates a device 3100 in a schematic view according to various embodiments.

The device 3100 may include a processor 1902 configured to perform a method according to various embodiments, e.g. any of the methods 2200, 2300, 2400, 2500, 2600, 2700, 2800.

For example, the processor 1902 may execute the code segments 1802 stored on the computer readable storage medium 3100, e.g. via a bus system of the device 3100. For example, the processor 1902 may carry out the method, e.g. any of the methods 2200, 2300, 2400, 2500, 2600, 2700, 2800. Optionally, the processor 1902 may be configured to set up the method using the database. Alternatively or additionally, the processor 1902 may be configured generate or modify the database according to results of the method, e.g. any of the methods 2200, 2300, 2400, 2500, 2600, 2700, 2800.

The processor 1902 may be configured for computing operations. For example, the processor 1902 may include or be formed from a microchip or an IC. For example, the processor 1902 may include or be formed from a CPU or a GPU. The processor 1902 may be a multi-core processor. The processor may be connected to a bus system of the device 3100.

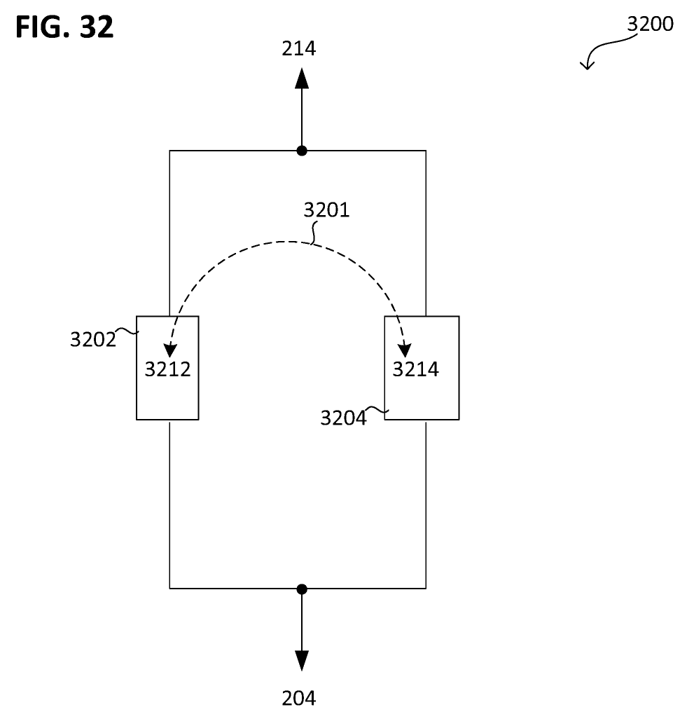

FIG. 32 illustrates a second electrical network 3200 in a schematic circuit diagram to various embodiments, similar to the second electrical networks described before.

According to various embodiments, the second electrical network 3200 may include a programmable first electrical element 3202 (also referred to as programmable first network element 3202) and a programmable second electrical element 3204 (also referred to as programmable second network element 3204). The programmable first electrical element 3202 and the programmable second electrical element 3204 may be coupled in parallel. The programmable first electrical element 3202 and the programmable second electrical element 3204 may be coupled between the source node 204 and the drain node 214

The programmable first electrical element 3202 may be programmed with first electrical characteristic 3212 representing a first parasitic element of the transistor, e.g. a first parasitic junction (e.g. a unipolar-junction, e.g. pn-junction or np-junction, e.g. a diode) of the transistor. The programmable second electrical element 3204 may be programmed with at least one second electrical characteristic 3214 representing a parasitic impedance of the transistor, e.g. a second parasitic element of the transistor coupled to the first parasitic element.

The second parasitic element may include a second parasitic junction having a greater polarity than the first parasitic element (e.g. a bipolar-junction, e.g. an npn-junction or a pnp-junction). Alternatively or additionally, the second parasitic element may include a capacitance of the first parasitic element.

The at least one second electrical characteristic 3214 may be coupled 3201 to the first electrical characteristic 3212, e.g. via at least one parameter 401, 901, 403. The coupled electrical characteristic 3212, 3214 may be configured to consider the coupling between the first parasitic element and the parasitic impedance.

The at least one parameter 401, 901, 403 may represent a voltage between the source node 204 and the drain node 214. For example, the at least one parameter 401, 901, 403 may include or be formed from a parameter 401 (also referred to as first parameter 401) representing a voltage between the source node 204 and the drain node 214. For example, the first parameter 401 may be a function of the voltage between the source node 204 and the drain node 214 or be the voltage between the source node 204 and the drain node 214.

Optionally, the at least one parameter 401, 901, 403 may include a further parameter 403 (also referred to as second parameter 403) representing a voltage between the source node 204 and the drain node 214 via the first parameter 401. For example, the further parameter 403 may be a function of the first parameter 401, e.g. in accordance with the first electrical characteristic 3212.

Optionally, the at least one parameter 401, 901, 403 may include another further parameter 903 (also referred to as third parameter 403) representing a voltage between the source node 204 and the drain node 214 via at least one of the first parameter 401 and the second parameter 403. For example, the third parameter 403 may be a function of at least one of the first parameter 401 (e.g. in accordance with the first electrical characteristic) and the second parameter 403 (e.g. in accordance with an electrical characteristic of an auxiliary electrical network).

According to various embodiments, the at least one parameter 401, 901, 403 may be a set of parameters including two or more parameters.

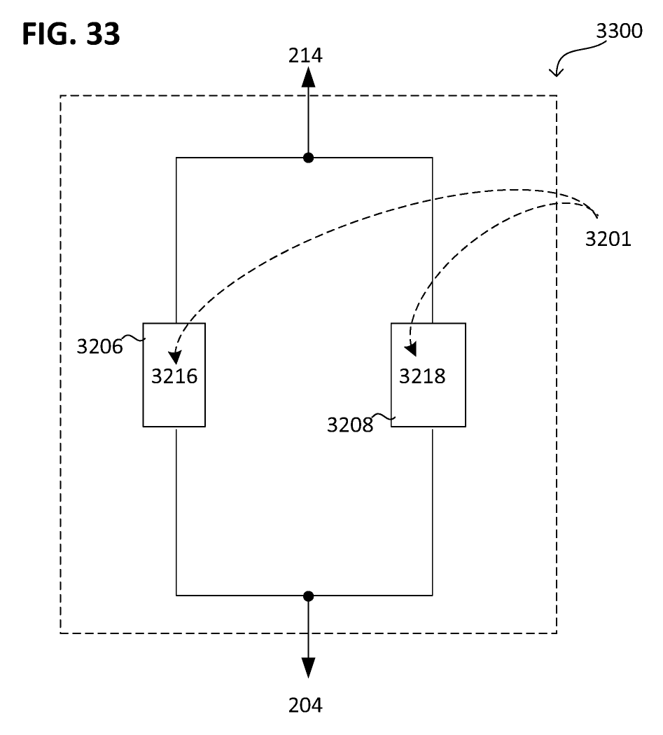

FIG. 33 illustrates a programmable second electrical element 3300 (also referred to as second network element 3300) in a schematic circuit diagram according to various embodiments, similar to the programmable second electrical element 3204 described before.

According to various embodiments, the second network element 3300 may include at least one of a programmable third electrical element 3206 and a programmable fourth electrical element 3208. Illustratively, the second network element 3300 may include or be formed from one or more other programmable electrical elements.

The programmable third electrical element 3206 (also referred to as programmable third network element 3206) and the programmable fourth electrical element 3208 (also referred to as programmable fourth network element 3208) may be coupled in parallel. The programmable third electrical element 3206 and the programmable fourth electrical element 3208 may be coupled between the source node 204 and the drain node 214.

The programmable third electrical element 3206 may include a third electrical characteristic 3216 (e.g. a charging characteristic 3216) representing a parasitic charge storage capability of the first parasitic element. The programmable fourth electrical element 3208 may include a fourth electrical characteristic 3218 (e.g. a bipolar characteristic 3218) representing the second parasitic junction of the transistor. In other words, the second electrical characteristic 3214 may include or be formed from at least one of the third electrical characteristic 3216 and the fourth electrical characteristic 3218.

The fourth electrical characteristic 3218 and the third electrical characteristic 3201 may be coupled 3201 to the first electrical characteristic 3212, e.g. the at least one parameter 401, 901, 403. The third electrical characteristic 3216 may further depend on a sign of the at least one parameter. The sign of the at least one parameter may be represented by the third parameter 901.

The programmable third electrical element 3202 may be configured for modeling the parasitic capacitance (Crr) and optionally for controlling the parasitic capacitance (e.g. via the auxiliary electrical network). The programmable fourth electrical element 3208 may be programmed for modeling a bipolar-junction, e.g. controlled by the at least one parameter 401, 901, 403.

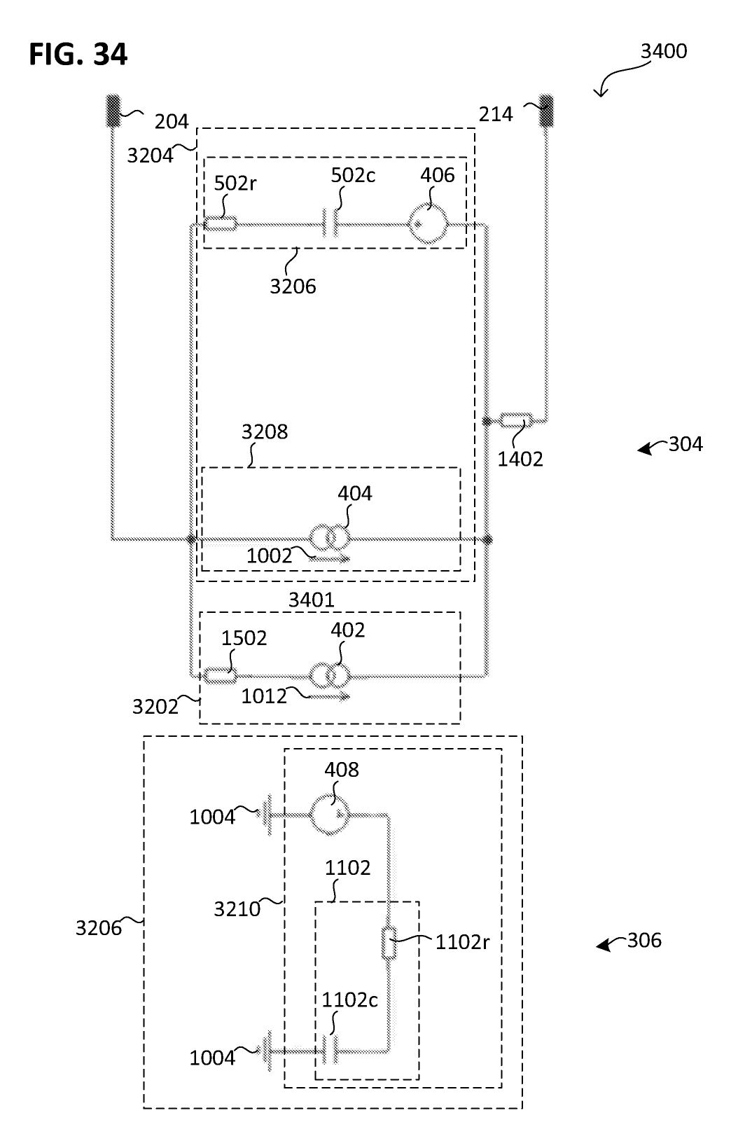

FIG. 34 illustrates a transistor model 3400 in a schematic circuit diagram according to various embodiments.

The transistor model 3400 may include the second electrical network 304 and the third electrical network 306. The third electrical network 306 may be also referred to as auxiliary electrical network 306. The second electrical network 304 may be understood as representing the physical structure of a transistor. The third electrical network 306 may be understood as representing an electrical property of the transistor (e.g., an operation mode correlated property of the transistor).

Illustratively, the physical structure of the transistor may be considered by the transistor model 3400 via the first current source 402 and the second current source 404. The first current source 402 and the second current source 404 may consider the diode current passing the transistor. The physical structure of the transistor may include various parasitic junctions, such as unipolar-junctions and bipolar-junctions.

The first current source 402 may represent a first parasitic junction, e.g. the parasitic unipolar-junction (e.g. pn-junction or np-junction) of the transistor. The second current source 404 may represent a second parasitic junction having a greater polarity than the first parasitic junction (in other words, having more polar interfaces than the first parasitic junction), e.g. the parasitic bipolar-junction (e.g. a parasitic npn-structure and/or parasitic pnp-structure, e.g., a parasitic bipolar transistor) of the transistor.

By way of example, the first current source 402 may be controlled by the first parameter 401, e.g. a voltage over the first current source 402. The first current source 402 may generate a current 1002 depending on the first parameter 401.

By way of example, the second current source 404 may be controlled by the second parameter 403, e.g. by current 1002 generated by the first current source 404, and by a further first parameter 401, e.g. a voltage over the second current source 404. Illustratively, the bipolar-junction may be controlled by the electrical current 1002 flowing through the parasitic unipolar junction. The current 1002 flowing through the parasitic unipolar-junction may be a base current of the parasitic bipolar-junction. In other words, the current 1002 flowing through the parasitic unipolar-junction may be applied to the base region of the parasitic bipolar-junction.

The first current source 402 and the second current source 404 may form a network loop 3401 together with the third resistor 1502. The third resistor 1502 may represent a track resistance of the transistor. The third resistor 1502 may define the base current, e.g. via defining the first parameter 401.

Illustratively, the network loop 3401 may consider two components of a current flow through the transistor. This may enable to reproduce a correct electrical characteristic of the transistor, e.g. representing a stored charge capability of the transistor. The current 1002 flowing through the parasitic unipolar-junction may inject charge carriers and therefore increase the charge stored by the transistor. The charge stored by the transistor may be discharged during a commutation operation. In other words, without considering the parasitic bipolar-junction, the charge stored by the transistor may be overestimated. Illustratively, without considering the parasitic bipolar-junction, the current 1002 flowing through the parasitic unipolar-junction may be overestimated, resulting in an overestimated charge carrier injection, resulting in an overestimated amount of charge stored by the transistor. By way of example, only the current 1002 flowing though the parasitic unipolar-junction may control the charge stored by the transistor.

For modeling the electric charge stored by the transistor, the charge storage capability (also referred to as Qrr) may be represented by the controlled capacitor 502, including the capacitor 502c and the controlled first voltage source 406 (also referred to as Qrr controller). The first voltage source 406 may be controlled by the third electrical network 306, e.g. via the third parameter 901.

The third electrical network 306 may be configured to reduce, e.g. substantially hide, the charge storage capability in a forward operation of the transistor. Therefore, the third electrical network 306 may control the first voltage source 406 such that a voltage over the capacitor 502c in a forward operation is less than in reverse operation, e.g. in a forward operation is substantially zero.

The third electrical network 306 may be configured to deflect the first voltage source 406 resulting in charging the capacitor 502c. In other words, the third electrical network 306 may control a voltage applied to the capacitor 502c via the first voltage source 406. The voltage generated by the first voltage source 406 may represent the charge carrier injection in a reverse operation (diode operation) into the parasitic capacitance.

In a commutation operation, e.g. switching from the reverse operation to the forward operation, the capacitor 502c may be discharged through the second resistor 1402 (also referred to as R_Socket) and through the first resistor 502r (also referred to as R_capacitor), and optionally through the first electrical network if coupled thereto.

According to various embodiments, the third electrical network 306 may include a programmable fifth electrical element 3210 (also referred to as a programmable fifth circuit 3210) coupled between equipotential nodes 1004. The programmable fifth electrical element 3210 may be programmed with fifth electrical characteristic representing a polarity dependency of the charge storage capability.

According to various embodiments, the third electrical network 306 may include the second voltage source 408 coupled between equipotential nodes 1004. The third electrical network 306 may further include the second RC-component 1102. The second RC-component 1102 may be coupled between equipotential nodes 1004 serially to the second voltage source 408. The second RC-component 1102 may include a fourth resistor 1102r (also referred to as R_B) and a further capacitor 1102c (also referred to as C_b).

According to various embodiments, the third parameter 901 may represent a voltage over the further capacitor 1102c. The first voltage source 406 may be configured to output a voltage representing a difference of the first parameter 401 and the third parameter 901.

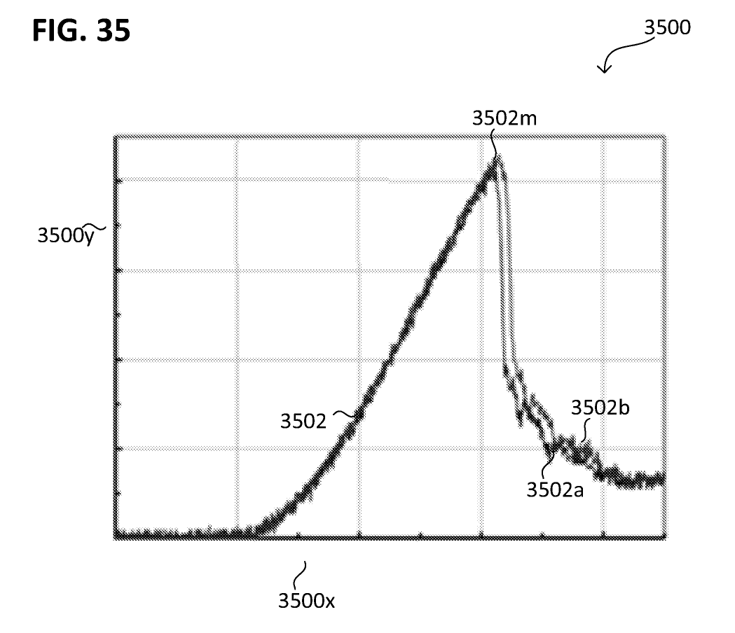

FIG. 35 illustrates an electrical characteristic 3502 of a transistor in a schematic diagram 3500 according to various embodiments. The diagram 3500 shows the current 3500y (e.g. in arbitrary units) flowing through the transistor (between source contact and drain contact) over the time 3500x (e.g. in arbitrary units).

The electrical characteristic 3502 may represent a measurement, e.g. of two transistors 3502a, 3502b differing in their socket length, e.g. by more than about 10%, e.g. by more than about 25%, e.g. may about 50%. For example, the two transistors may differ in their socket length by more than about 1 micrometer (μm), by more than about 2 μm, by about 4 μm. Illustratively, by increasing the socket length, e.g. from 8 μm to 12 μm, may increase the length of the transistor resulting in an increased transistor volume. By increasing the socket length, the charge storage capability of the transistor may be increased. Therefore, the transistor having the greater socket length may store more charge than the transistor having the smaller socket length. The incensement of the charge storage capability (also referred to as parasitic capacitance) may be represented by a greater capacitance of capacitor 502c (also referred to as first capacitor 502c).

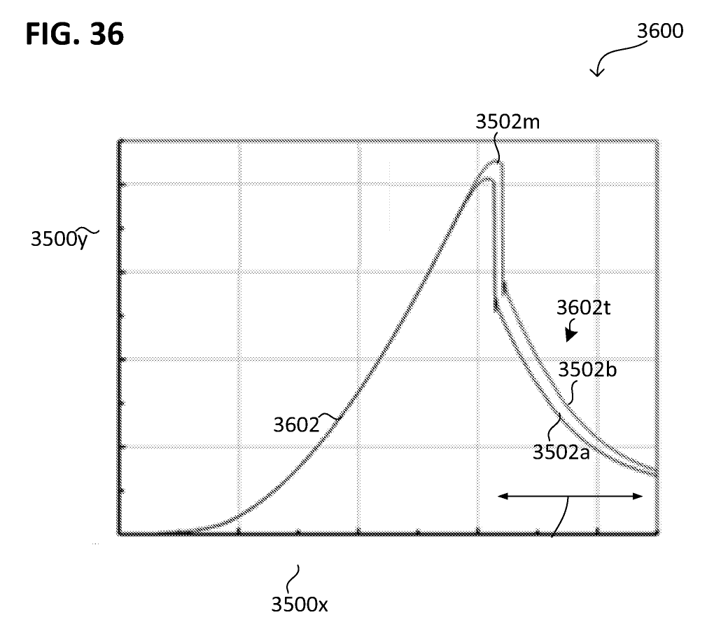

FIG. 36 illustrates an electrical characteristic 3602 of a transistor model (transistor model characteristic 3602) in a schematic diagram 3600 according to various embodiments. The diagram 3600 shows the current 3500y (e.g. in arbitrary units) flowing through the transistor (between source contact and drain contact) over the time 3500x (e.g. in arbitrary units). The electrical characteristic 3602 may represent a simulation via a transistor model according to various embodiments. The simulation may include performing an electric network analysis using the transistor model. The parameters of the transistor model may be adjusted to reproduce the measurements in accordance with transistors 3502a, 3502b.

The first resistor 502r and the second resistor 1402 may be in sum (also referred to as R) greater than the resistance of all other resistors in the transistor model 3600. The sum R of the resistances of the first resistor 502r and the second resistor 1402 may define a time i (also referred to as relaxation time τ) in conjunction with a capacitance C of the controlled capacitor 502 (e.g. its capacitor 502c), wherein τ=C·R. By adjusting at least one of the sum R and the capacitance C, the time i may be adjusted.

Via adjusting the time τ, a current tail 3602t (current decrease over the relaxation time τ) of the electrical characteristic may be defined. The current tail may occur after a current maximum 3502m (also referred to as I_rrm).

This simulation result may be understood as example, representing the consideration of changings in the technology by the transistor model according to various embodiments. By adjusting the set of model parameters (resistances and/or capacitances) of the transistor model, the physical structure of the transistor may be considered.

After adjusting, the set of model parameters may be stored in the database. This may enable to form a database representing a plurality of transistor differing in their physical structure (also referred to as transistor type). The database may include a set of model parameter for each transistor type of the plurality of transistor.

Alternatively or additionally, a set of model parameter representing a transistor type may be loaded from the database to set up a transistor model. The readily set up a transistor model may be incorporated in a circuit model representing an electrical device, circuit and the like. The circuit model may be used to simulate the electrical device, circuit and the like, e.g. by performing a network analysis using the circuit model. For example, the circuit model may be a commutation circuit model.

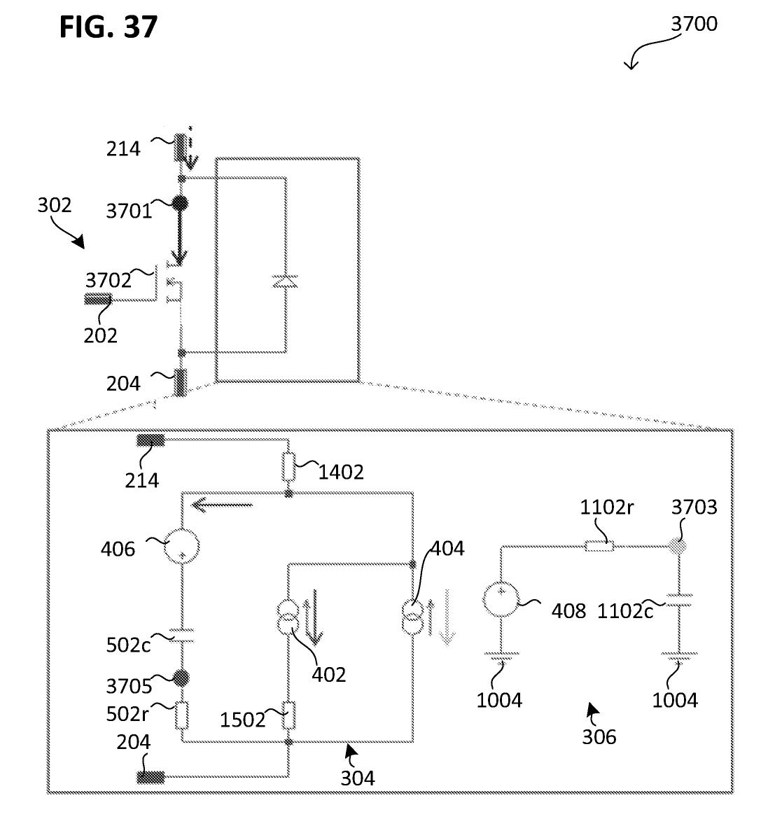

FIG. 37 illustrates a transistor model 3700 in a schematic circuit diagram according to various embodiments, similar to the previously described transistor models (see for example, FIG. 3).

The first electrical network may include a switch 3702 representing the switching characteristic of the transistor, for example, a unipolar transistor like a MOSFET as illustrated in FIG. 37. The switch 3702 may be configured for modeling a switching characteristic of the transistor. The switch 3702 may be configured to control a connection (e.g. resistance) between the drain node 214 and the source node 204 in dependency to an electrical potential of the gate node 202.

For example, a voltage between the gate node 202 and the source node 204 (also referred to as gate-to-source voltage) may control an electric resistance through the switch 3702 between the drain node 214 and the source node 204 (also referred to as drain-to-source resistance), and respectively control a current through the switch 3702 flowing between the drain node 214 and the source node 204 (also referred to as drain-to-source current) in dependency on a voltage between the drain node 214 and the source node 204 (also referred to as drain-to-source voltage). For example, the switch 3702 may alter the drain-to-source resistance steady in dependency on the gate-to-source voltage. Illustratively, the switch 3702 may be configured as variable resistor controlled by the gate node 202 (may also referred to as controlled resistor 3702).

For example, the drain-to-source current may be proportional to the drain-to-source voltage.

According to various embodiments, the transistor model may enable:
a higher accuracy for variable chip sizes, e.g. for the diode characteristic;
a correct current scaling of the stored charge in a commutation operation, illustratively, due to the transistor model inspired by the physical structure of the transistor (in particular due to considering the parasitic bipolar-junction and/or parasitic capacitance);
a correct chip area scaling of the stored charge in a commutation operation, illustratively, due to the transistor model inspired by the physical structure of the transistor (in particular due to considering the parasitic bipolar-junction and/or parasitic capacitance);
predictive estimation for changing of technological parameters due to the transistor model inspired by the physical structure of the transistor (in particular due to considering the parasitic bipolar-junction and/or parasitic capacitance);
due to hiding of the second network in forward operation, the model may be incorporated to various conventional transistor models;
reducing time consumption for performing a network analysis (e.g. for simulating); and/or
reducing time consumption for implementing the transistor model (e.g. for simulating), illustratively, due to obsolete corrections.

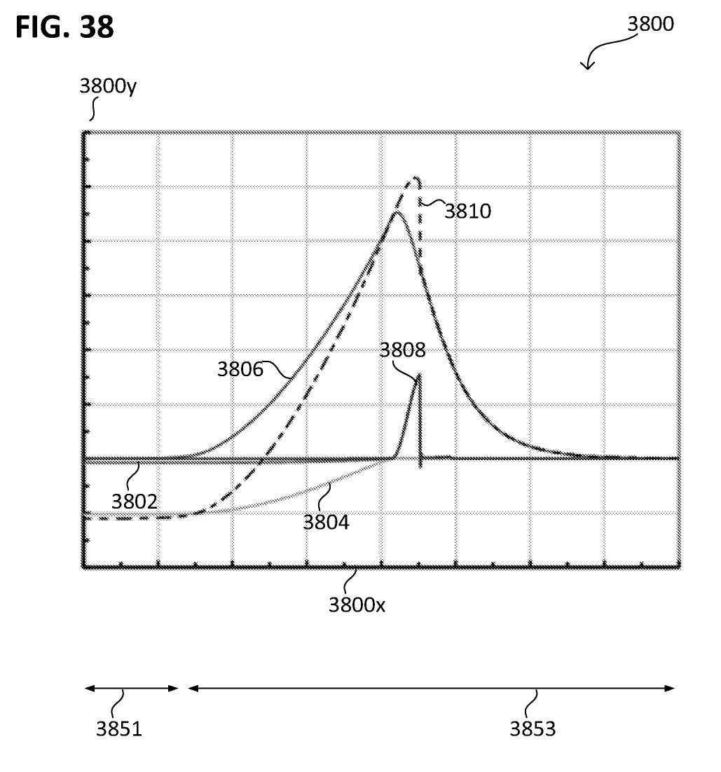

FIG. 38 illustrates various electrical characteristics used in a transistor model in a schematic diagram 3800 according to various embodiments. The diagram 3800 shows the current 3800y (e.g. in arbitrary units) over the time 3800x (e.g. in arbitrary units).

The electrical characteristics may reconstruct the electric properties of the transistor during a commutation operation, e.g. switching from forward operation 3851 to reverse operation 3853.

A first electrical characteristic 3802 may represent a current through the first parasitic element (e.g. generated by the first current source 402), e.g. directing from the drain node 214 to the source node 204. A second electrical characteristic 3804 may represent a current through the second parasitic element (e.g. generated by the second current source 404, e.g. directing from the drain node 214 to the source node 204. A third electrical characteristic 3806 may represent a current arising from the charge storage capability (e.g. by charging the capacitor 502c), e.g. directing from the drain node 214 to the source node 204. A further electrical characteristic 3808 may represent a current through the switch 3702 (directing from the drain node 214 to the source node 204), e.g. between a first node 3701 (see FIG. 37) and the source node 204.

A transistor model characteristic 3810 may represent a current from the drain node 214 to the source node 204. Illustratively, the transistor model characteristic 3810 may be a sum of the first electrical 3802, the second electrical characteristic 3804, the third electrical characteristic 3806 and the further electrical characteristic 3808.

The various electrical characteristics 3802, 3804, 3806, 3808, 3810 may be also referred to as current-time characteristics 3802, 3804, 3806, 3808, 3810.

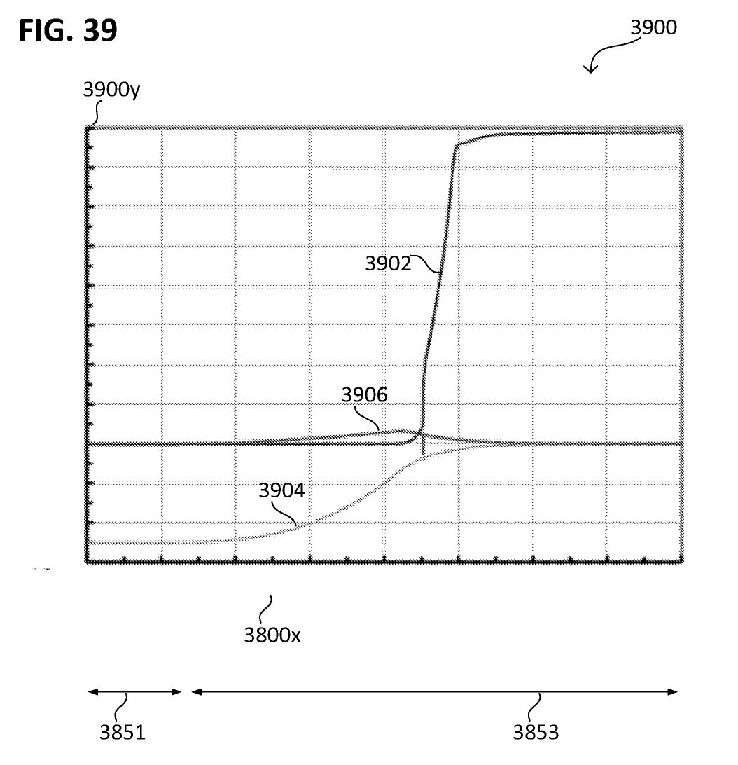

FIG. 39 illustrates various electrical characteristics of a transistor in a schematic diagram 3900 according to various embodiments. The diagram 3900 shows the voltage 3900y (e.g. in arbitrary units) over the time 3800x (e.g. in arbitrary units).

The electrical characteristics may represent the electric properties of the transistor during a commutation operation, e.g. switching from forward operation 3851 to reverse operation 3853.

A further electrical characteristic 3902 may represent a voltage over the first switch 3702 (directing from the drain node 214 to the source node 204). A third electrical characteristic 3904 may represent a voltage of the second RC-component 1102, e.g. over the further capacitor 1102c (also referred to as second capacitor 1102c), e.g. between a second node 3703 (see FIG. 37) and a reference potential (e.g. at the two equipotential nodes 1004). A further third electrical characteristic 3906 may represent a voltage of the second electrical network, e.g. of the first RC-component 502c, 502r, e.g. over the first resistor 502r, e.g. between a third node 3705 (see FIG. 37) and a reference potential (e.g. at the two equipotential nodes 1004).

For example, the third parameter 901 may represent (e.g. be identical or a function of) the voltage of the third electrical network, e.g. a voltage of the second RC-component 1102 (also referred to as third control parameter).

The various electrical characteristics 3902, 3904, 3906 may be also referred to as voltage-time characteristics 3902, 3904, 3906.

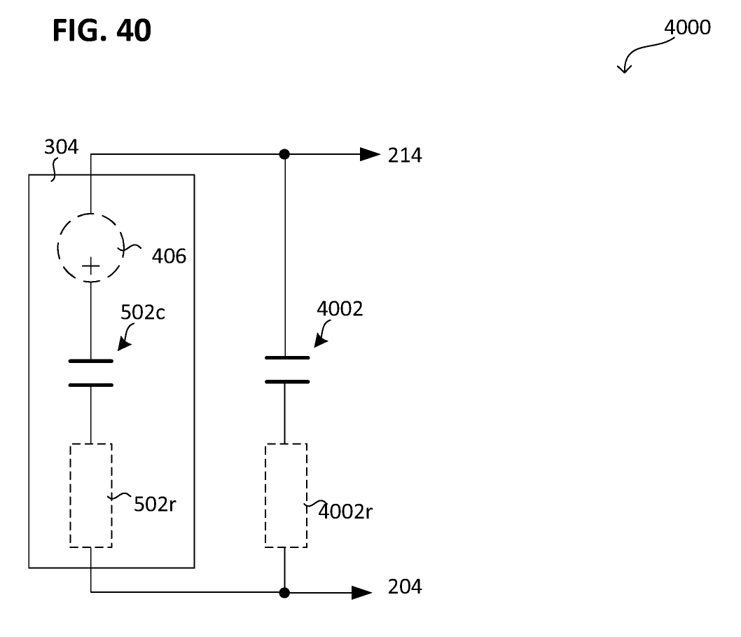

FIG. 40 illustrates a transistor model 4000 in a schematic circuit diagram according to various embodiments, similar to the second electrical network described before.

According to various embodiments, the transistor model 4000 may include the second electrical network 304. The transistor model 4000 may include a third capacitor 4002 coupled between the source node 204 and the drain node 214 and in parallel to the first capacitor 502c.

Optionally, the second electrical network 304 may include at least one of the first voltage source 406 and the first resistor 502r.

The third capacitor 4002 (also referred to as C_Qrr2) may represent a charge storage capability of a rim of the transistor, e.g. in case of a transistor cell.

Optionally, the transistor model 4000 may include a fifth resistor 4002r coupled between the source node 204 and the drain node 214 and in parallel to the first capacitor 502c and serially to the third capacitor 4002. The fifth resistor 4002r may be configured to discharge the third capacitor 4002 slower than the first capacitor 502c. In other words, a product of a capacity of the third capacitor 4002 and a resistivity of the fifth resistor 4002r may be greater than a product of a capacity of the capacitor 502s and a resistivity of the first resistor 502r.

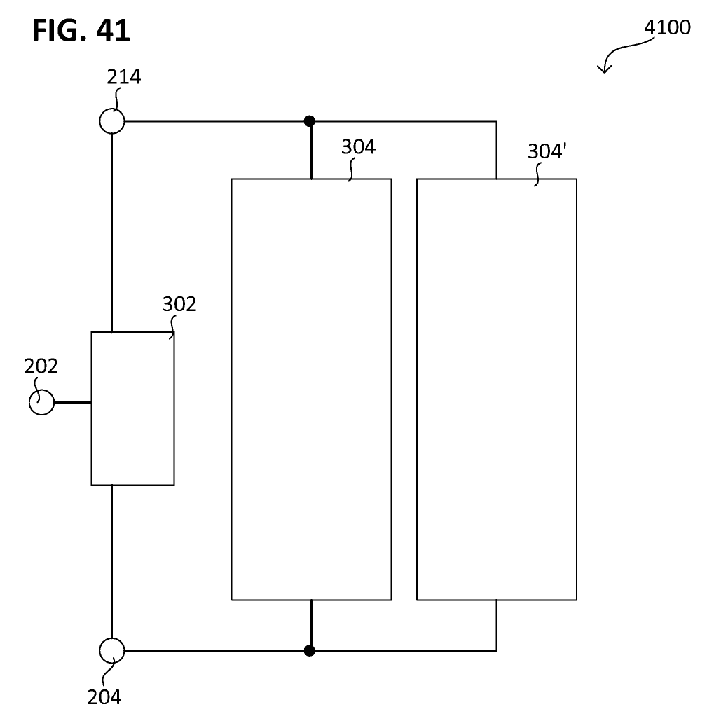

FIG. 41 illustrates a transistor model 4100 in a schematic circuit diagram according to various embodiments, similar to the previously described transistor models.

The transistor model 4100 may include the second electrical network 304. The second electrical network 304 may any of the second electrical networks described herein.

According to various embodiments, the transistor model 4100 may include a further second electrical network 304′. The further second electrical network 304′ may be coupled between the source node 204 and the drain node 214 parallel to the second electrical network 304 and parallel to the first electrical network 302. The further second electrical network 304′ may be any of the second electrical networks described herein. Illustratively, the further second electrical network 304′ may represent a charge storage capability of a rim of the transistor, e.g. in case of a transistor cell.

According to various embodiments, the second electrical network 304 and the further second electrical network 304′ may be the same.

Alternatively, the further second electrical network 304′ may have a controlled current source less than the second electrical network 304, e.g. the second current source 404. Alternatively or additionally, the second electrical network 304′ may have a controlled voltage source less than the second electrical network 304, e.g. the first voltage source 406.

For example, the further second electrical network 304′ may include a first RC-component 502c, 502r. The first RC-component 502c, 502r of the further second electrical network 304′ may define a time dependency of charging and/or discharging a charge storage capability of the rim.

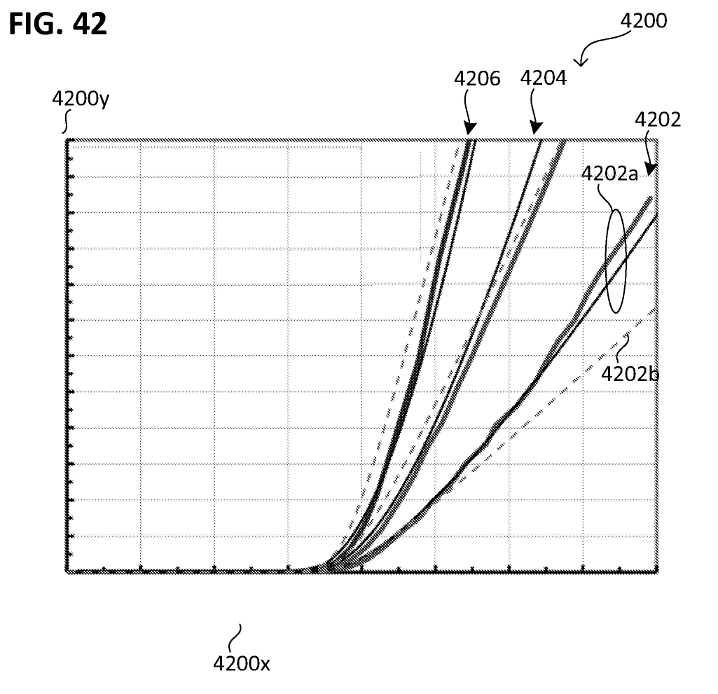

FIG. 42 illustrates various electrical characteristics in a schematic diagram 4200 according to various embodiments. The diagram 4200 shows the current 4200y (e.g. in arbitrary units) over the voltage 4200x (e.g. in arbitrary units), e.g. a reverse operation characteristic.

The electrical characteristics 4202, 4204, 4206 may each represent a measurement from a physical transistor and the corresponding simulation using a transistor model according to various embodiments (solid lines) in comparison to a conventional simulation (dashed line).

For a first electrical characteristic 4202, a deviation 4202a of the simulation using a transistor model from the measurement is less than a deviation 4202b of the conventional simulation.

Each electrical characteristics 4202, 4204, 4206 may represent the transistor and the respective transistor model in a reverse operation. In this case, the electrical characteristic 4202, 4204, 4206 may be also referred to as diode characteristic 4202, 4204, 4206.

According to various embodiments, using the transistor model according to various embodiments may be revealed by the bipolar-junction contribution of the diode characteristic 4202, 4204, 4206.

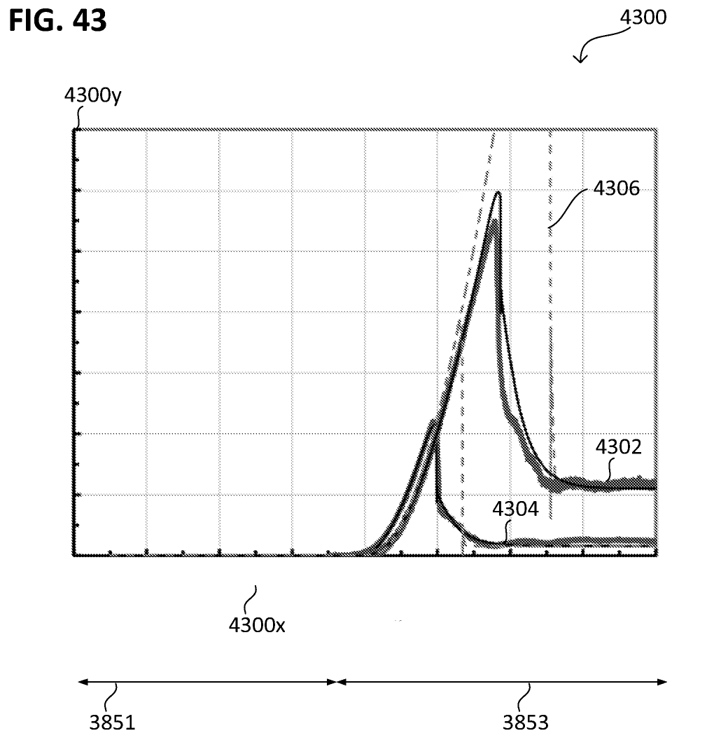

FIG. 43 illustrates various electrical characteristics of a transistor in a schematic diagram 4300 according to various embodiments. The diagram 4300 shows the current 4300y (e.g. in arbitrary units) over the voltage 4300x (e.g. in arbitrary units), e.g. in a commutation operation.

The electrical characteristics 4302, 4304 may each represent a measurement of a physical transistor and the corresponding simulation using a transistor model according to various embodiments (solid lines) in comparison to a conventional simulation 4306 (dashed line).

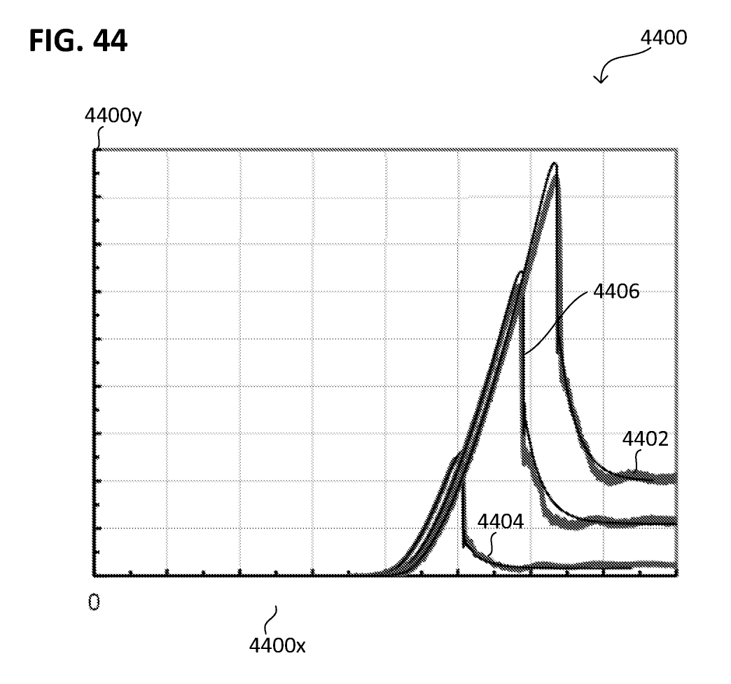

FIG. 44 illustrates various electrical characteristics of a transistor in a schematic diagram 4400 according to various embodiments. The diagram 4400 shows the current 4400y (e.g. in arbitrary units) flowing through the transistor (between source contact and drain contact) over the voltage 4400x (e.g. in arbitrary units), e.g. in a commutation operation.

The electrical characteristics 4402, 4404, 4406 may each represent a measurement and the corresponding simulation using a transistor model according to various embodiments (solid lines).

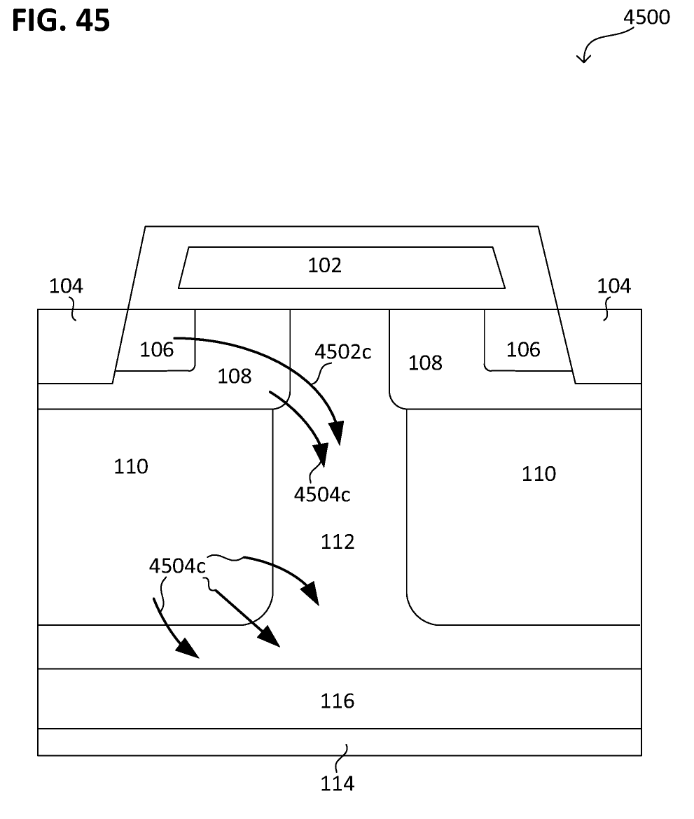

FIG. 45 illustrates a transistor 4500 in a schematic cross sectional view or side view according to various embodiments, showing its physical structure.

The transistor may include the gate contact 102, the drain contact 114, and the source contact 104. Further, the transistor 4500 may include the following doped regions (doped semiconductor regions): the first doped region 106, the second doped region 108, the third doped region 112, the fourth doped region 110 and the fifth doped region 116. The transistor 4500 may be a MOSFET.

During operating the transistor 4500, a first current 4504c may flow through the parasitic unipolar junction 110, 112 (illustratively, formed from the fourth doped region 110 and the third doped region 112). During operating the transistor 4500, a second current 4502c may flow through the parasitic bipolar-junction 106, 108, 112 (illustratively, formed from the first doped region 106, the second doped region 108, and the third doped region 112).

The first current 4504c may inject charge carriers in at least one of a capacitance of the parasitic unipolar-junction 110, 112 (also referred to as parasitic capacitance) and the parasitic bipolar-junction 106, 108, 112, thereby reducing a parasitic impedance of the transistor, e.g. defined by at least one of the parasitic capacitance and the parasitic bipolar-junction 106, 108, 112. Alternatively or additionally, charge carriers may be injected from the second doped region 108 into the third doped region 112.

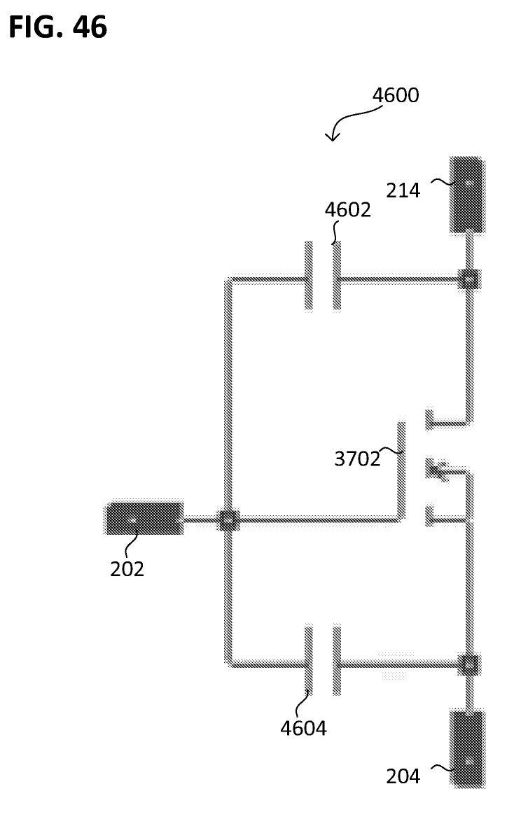

FIG. 46 illustrates a first electrical network 4600 in a schematic circuit diagram according to various embodiments, similar to the first electrical network described before.

The first electrical network 4600 may include a controlled resistor 3702 coupled between the source node 204 and the drain node 214. The resistor 3702 may be controlled by the gate node 202.

The first electrical network 4600 may further include a fourth capacitor 4602 representing a (e.g. static) charge storage capability of the transistor between drain contact and gate contact. The first electrical network 4600 may further include a fifth capacitor 4604 representing a (e.g. static) charge storage capability of the transistor between source contact and gate contact.

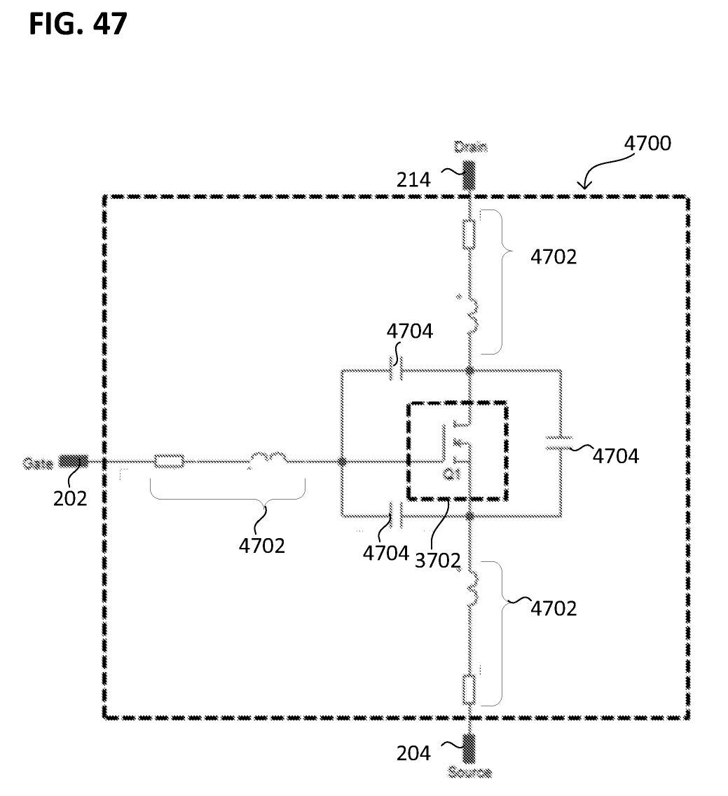

FIG. 47 illustrates a first electrical network 4700 in a schematic circuit diagram according to various embodiments, similar to the first electrical network described before.

According to various embodiments, the first electrical network 4700 may include a plurality of RL-circuits 4702 (each including a resistor and an inductance). At least one RL-circuit of the plurality of RL-circuits 4702 may be coupled between the controlled resistor 3702 and each of: the source node 204, the drain node 214 and the gate node 202. The plurality of RL-circuits 4702 may represent a contact structure contacting at least one of the source contact, the gate contact, and the drain contact of the transistor, e.g. parasitic resistances and inductances arising from contacting the transistor.

According to various embodiments, the first electrical network 4700 may include a plurality of capacitors 4704. At least one capacitor of the plurality of capacitors 4704 may be coupled between two of: the source node 204, the drain node 214 and the gate node 202. The plurality of capacitors 4704 may represent parasitic capacitance of the transistor between each two of source contact, the gate contact, and the drain contact of the transistor.

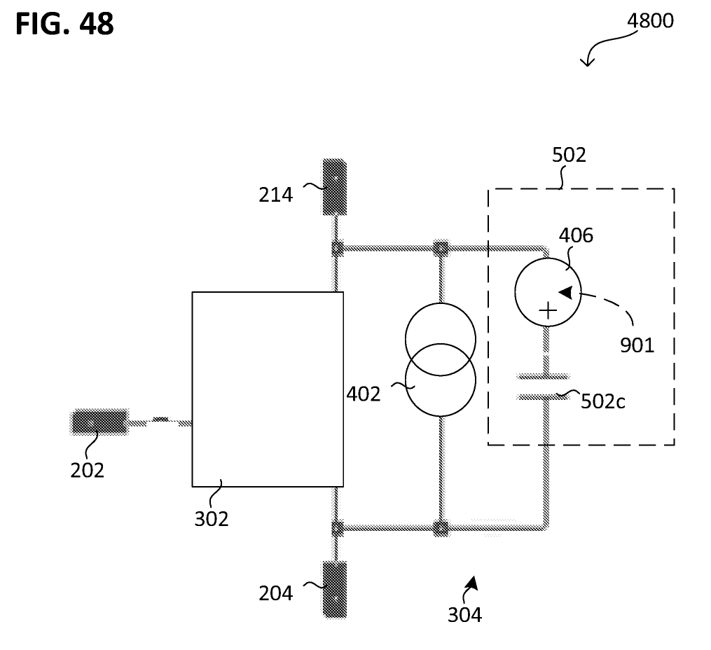

FIG. 48 illustrates a transistor model 4800 in a schematic circuit diagram according to various embodiments, similar to the transistor models described before.

The transistor model 4800 may include the first electrical network 302 coupled between the source node 204, the drain node 214 and the gate node 202.

The transistor model 4800 may the second electrical network 304 coupled between the source node 204 and the drain node 214 and in parallel to the first electrical network 302.

The second electrical network 304 may include the first current source 402 and the controlled capacitance component 502 coupled in parallel. The controlled capacitance component 502 may include or be formed from the first voltage source 406 and the capacitor 502c coupled serially to each other.

Illustratively, the controlled capacitance component 502 may represent a parasitic capacitance of the transistor. The parasitic capacitance may be controlled by at least one parameter 401, 403, 901, e.g. at least one of the first parameter 401, the third parameter 901 and second parameter 403. The first voltage source 406 may be configured to be controlled by an operation mode of the transistor (in other words, by the polarity between source node 204 and drain node 214).

For example, the first voltage source 406 may be configured to compensate a voltage over the first capacitor 502c at least partially for a first polarity. The first polarity may represent a first operation of the transistor (e.g. in forward operation). Illustratively, the first voltage source 406 may be configured to hide the charge storage capability in the first operation.

Alternatively or additionally, the first voltage source 406 may be configured to transfer more electric charges to the first capacitor 502c (illustratively, charge the first capacitor 502c) for a second polarity than in the first polarity. The second polarity may be opposite the first polarity. The second polarity may represent a second operation of the transistor (e.g. in reverse operation). Illustratively, the first voltage source 406 may be configured to charge the capacitor 502c in the second operation.

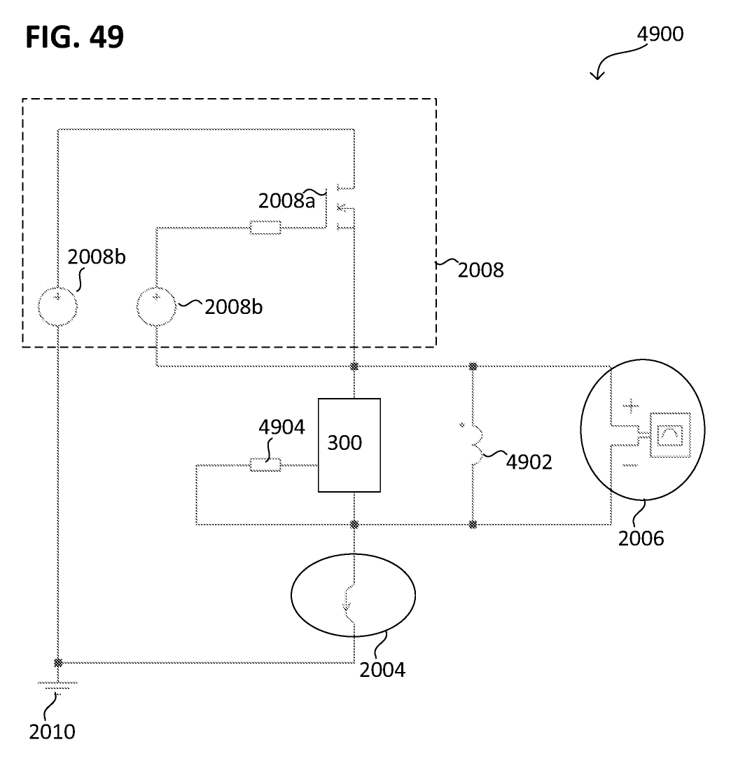

FIG. 49 illustrates a commutation circuit model 4900 in a schematic circuit diagram according to various embodiments.

The commutation circuit model 4900 may include a transistor model 300 according to various embodiments, e.g. any of the herein described transistor models. The commutation circuit model 4900 may further include a reference node 2010. The reference node 2010 may define a reference potential, e.g. electrical ground. The commutation circuit model 4900 may further include a first sensor 2004 coupled between the transistor model 2002 (e.g. its source node 204) and the reference node 2010. The first sensor 2004 may be configured to sense an electrical current, e.g. through the transistor model 300.

The commutation circuit model 4900 may further include a signal generator 2008. The signal generator 2008 may be configured to generate an electrical signal, e.g. a current and/or a voltage. The electrical signal may be supported to the transistor model 2002 (e.g. to its drain node 214). The commutation circuit model 4900 may further include a second sensor 2006 coupled parallel to the transistor model 2002 (e.g. to source node 204 and drain node 214), e.g. between the signal generator 2008 and the first sensor 2004. The second sensor 2006 may be configured to sense an electrical voltage, e.g. over the transistor model 300.

The signal generator 2008 may be coupled between the drain node 214 of the transistor model 300 and the reference node 2010. The first sensor 2004 may be coupled between the source node 204 of the transistor model 300 and the reference node 2010. The second sensor 2006 may be coupled between the source node 204 and the drain node 214 of the transistor model 300.

Further, the commutation circuit model 4900 may include an inductance 4902 coupled between the first sensor 2004 and the signal generator 2008 and parallel to the transistor model 300. Illustratively, the inductance 4902 may be configured to induce a diode current in a diode operation.

Further, the commutation circuit model 4900 may include a resistor 4902 coupled between the transistor model 300 (its gate node 202) and the first sensor 2004.

The signal generator 2008 may include a controlled switch 2008a, a switch controller 2008b (e.g. a controlled voltage source), a bias generator 2008c (e.g. a controlled voltage source). The switch 2008a may be controlled by the switch controller 2008b (also referred to as switch driver). The bias generator 2008c may be configured to generate a bias signal, which is modulated by the switch 2008a according to the output of the switch controller 2008b.

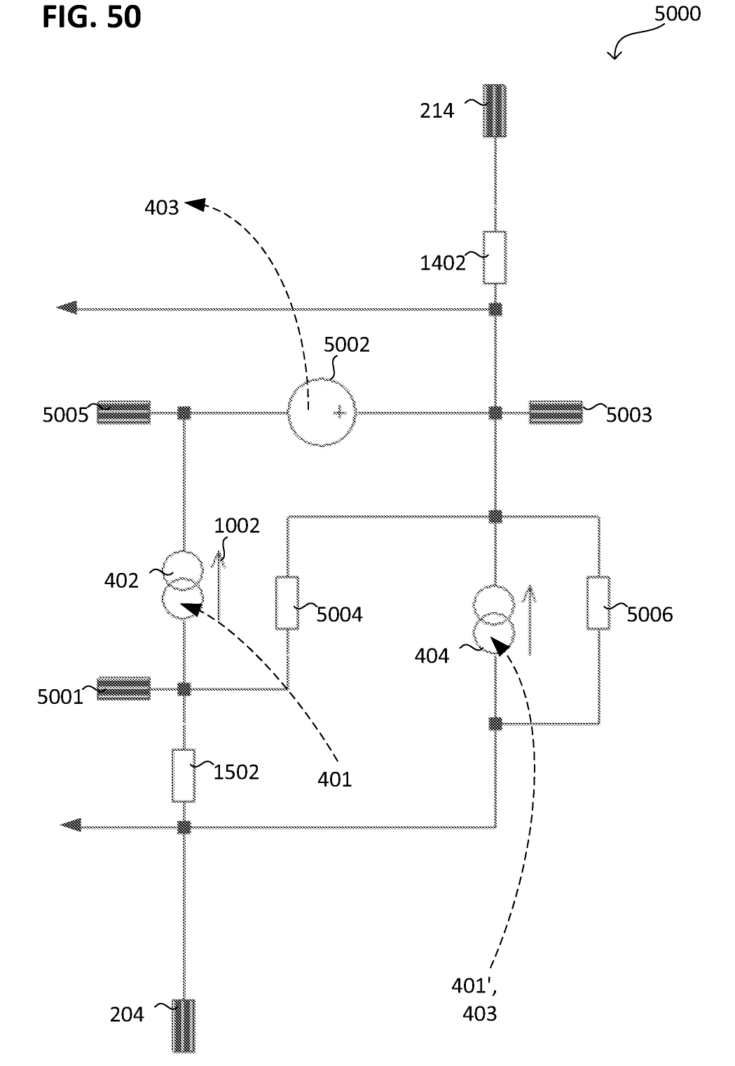

FIG. 50 illustrates a second electrical network 5000 in a schematic detailed circuit diagram view according to various embodiments, similar to the second electrical network described before.

According to various embodiments, the second electrical network 5000 may include a first intermediate resistor 5004 coupled between a first intermediate node 5001 and a second intermediate node 5003. The first intermediate node 5001 may be coupled between the first current source 402 and the source node 204, e.g. between the first current source 402 and the third resistor 1502, if present. The second intermediate node 5001 may be coupled between the second current source 404 and the drain node 214, e.g. e.g. between the second current source 404 and the second resistor 1402 if present.

Further, the second electrical network 5000 may include a second intermediate resistor 5006 coupled between the second intermediate node 5003 and the source node 204 parallel to the second current source 404.

According to various embodiments, the second electrical network 5000 may include a parameter generator 5002 coupled serially to the first current source 402, e.g. between the drain node 214 (or the second intermediate node 5003) and the first current source 402 (or a third intermediate node 5005). The parameter generator 5002 may be configured to generate the second parameter 403 representing an output of first current source 402. For example, the parameter generator 5002 may be a sensor configured to sense a current 1002 generated by the first current source 402. For example, the current 1002 may be used as second parameter 403. The parameter generator 5002 may be configured to supply the generated second parameter 403 to at least one of the second current source 404 and the third network 306 (e.g. its second voltage source 408), e.g. for controlling them.

The first current source 402 may be configured to generate the current 1012 based on at least one of a further first parameter 401, e.g. in accordance with the first electrical characteristic. By way of example, the first parameter 401 may be a voltage over the first current source 402.

The second current source 404 may be configured to generate a further current 1012 based on at least one of a further first parameter 401′ and the second parameter 403, e.g. in accordance with the second electrical characteristic. By way of example, the further first parameter 401′ may be a voltage over the second current source 404.

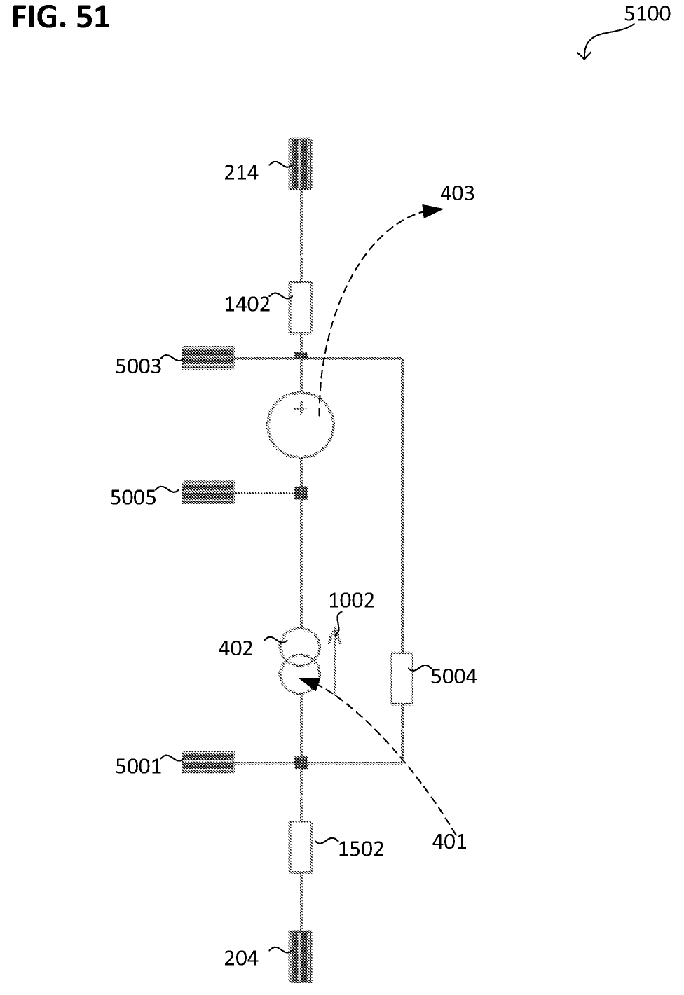

FIG. 51 illustrates a second electrical network 5100 in a schematic detailed circuit diagram according to various embodiments, similar to the second electrical network described before.

The second electrical network 5100 may be configured to model the diode current through the transistor.

Further, various embodiments will be described in the following.
1. A transistor model for a computer based simulation of a field effect transistor, the transistor model including:
   a first electrical network coupled between a drain node, a source node and a gate node, wherein the first electrical network is configured to represent an electrical characteristic of the field effect transistor in a forward operation;
   a second electrical network coupled parallel to the first electrical network and between the source node and the drain node, wherein the second electrical network is configured to represent an electrical characteristic of the field effect transistor in at least one of a commutation operation and a reverse operation;
   wherein the second electrical network includes:
      a controlled first source representing a parasitic junction of the field effect transistor;
      at least one controlled second source representing a charge injection dependent parasitic impedance of the field effect transistor;
      wherein the controlled first source and the at least one controlled second source are coupled in parallel; and
      wherein the controlled first source and the at least one controlled second source are coupled via at least one parameter such that a charge injection from the parasitic junction into the parasitic impedance is considered.
2. The transistor model of clause 1,
   wherein the parasitic junction includes or is formed from a unipolar-junction of the transistor (e.g. a diode).
3. The transistor model of clause 1 or 2,
   wherein the charge carrier injection reduces the parasitic impedance.
4. The transistor model of one of the clauses 1 to 3,
   wherein the parasitic impedance includes at least one of a further parasitic junction and a capacitive impedance (can also be referred to as capacitive reactance) of the parasitic junction; and/or
   wherein the at least one second controlled source includes at least one of a second source representing a further parasitic junction, and a third source representing a capacitive impedance of the parasitic junction.
5. The transistor model of clause 4,
   wherein the further parasitic junction includes more polar interfaces than the parasitic junction.
6. The transistor model of clause 4 or 5,
   wherein the further parasitic junction includes or is formed from a bipolar-junction of the transistor.
7. The transistor model of clause 6,
   wherein the carrier injection includes a base load of the parasitic bipolar-junction of the transistor.
8. The transistor model of one of the clauses 4 to 7,
   wherein the carrier injection includes charging the capacitive impedance of the parasitic junction.
9. The transistor model of one of the clauses 1 to 8,
   wherein the at least one controlled second source includes at least two controlled sources (also referred to as second source and third source) coupled in parallel to each other.
10. The transistor model of one of the clauses 1 to 9,
   wherein the controlled first source (also referred to as first current source) is configured to output a first current.
11. The transistor model of one of the clauses 1 to 10,
   wherein an output of the controlled first source is controlled by a first parameter of the at least one parameter representing a potential difference of the source node and the drain node.
12. The transistor model of one of the clauses 1 to 12,
   wherein an output of the controlled first source is in accordance with a first electrical characteristic representing the parasitic junction.
13. The transistor model of one of the clauses 1 to 12,
   wherein a first electrical characteristic of the controlled first source defines an output of the controlled first source in dependency to a first parameter of the at least one parameter controlling the controlled first source.
14. The transistor model of one of the clauses 1 to 13, wherein the controlled first source is controlled by a first parameter of the at least one parameter representing at least one of:
   a voltage over the controlled first source; and
   a voltage from the source node to the source node.
15. The transistor model of one of the clauses 1 to 14,
   wherein a second source of the at least one controlled second source (also referred to as second current source) is configured to output a second current.
16. The transistor model of one of the clauses 1 to 15,
   wherein an output of a second source of the at least one controlled second source is controlled by at least one of:
   a second parameter of the at least one parameter representing an output of the controlled first source; and
   a further first parameter of the at least one parameter representing a potential difference of the source node and the drain node.
17. The transistor model of one of the clauses 1 to 16,
   wherein an output of a second source of the at least one controlled second source is in accordance with a second electrical characteristic representing a further parasitic junction of the transistor.
18. The transistor model of one of the clauses 1 to 17,
   wherein a second electrical characteristic of a second source of the at least one controlled second source defines an output of the second source in dependency to at least one of a further first parameter and a second parameter of the at least one parameter controlling the second source.
19. The transistor model of one of the clauses 1 to 18, wherein a second source of the at least one controlled second source is controlled by a second parameter of the at least one parameter representing at least one of:
   a voltage over the controlled first source; and
   an output of (e.g. a current generated by) the controlled first source; and/or
   wherein the second source of the at least one controlled second source is controlled by a further first parameter of the at least one parameter representing at least one of:
   a voltage over the controlled first source;
   a voltage over the second source of the at least one controlled second source; and
   a voltage from the source node to the source node.
20. The transistor model of one of the clauses 1 to 19,
   wherein a third source of the at least one controlled second source (also referred to as first voltage source) is configured to output a first voltage.
21. The transistor model of one of the clauses 1 to 20,
   wherein an output of a third source of the at least one controlled second source is controlled by at least one of another first parameter and a third parameter of the at least one parameter representing an output of the controlled first source.
22. The transistor model of one of the clauses 1 to 21,
   wherein an output of a third source of the at least one controlled second source is in accordance with a third electrical characteristic representing a charge storage characteristic of the parasitic junction.
23. The transistor model of one of the clauses 1 to 22,
   wherein a third electrical characteristic of a third source of the at least one controlled second source defines an output of the third source in dependency to at least one of another first parameter and a third parameter of the at least one parameter controlling the third source.
24. The transistor model of one of the clauses 1 to 23, wherein a third source of the at least one controlled second source is controlled by a third parameter of the at least one parameter representing at least one of:
   an output of a fourth source;
   a voltage over a capacitor of a third network; and
   a voltage of an RC-component a third network;
   and/or
   wherein the third source of the at least one controlled second source is controlled by another first parameter of the at least one parameter representing at least one of:
   a voltage over the controlled first source;
   a voltage over the third source of the at least one controlled second source; and
   a voltage from the source node to the source node.
25. The transistor model of one of the clauses 1 to 24,
   wherein a third parameter of the at least one parameter controlling an output of a third source of the at least one controlled second source represents an output of the controlled first source via a third electric network.
26. The transistor model of one of the clauses 1 to 25, further including:
   a fourth source (also referred to as second voltage source) configured to output a second voltage.
27. The transistor model of clause 26,
   wherein an output of the fourth source of the at least one controlled second source is controlled by a second parameter of the at least one parameter representing an output of the controlled first source.
28. The transistor model of clause 26 of or 27,
   wherein an output of the fourth source is in accordance with a fourth electrical characteristic representing an operation mode dependency of a charge storage capability of the parasitic junction.
29. The transistor model of one of the clauses 26 to 28,
   wherein a fourth electrical characteristic of the fourth source defines an output of the fourth source in dependency to a second parameter of the at least one parameter controlling the fourth source.
30. The transistor model of one of the clauses 26 to 29, wherein the fourth source is controlled by a second parameter of the at least one parameter representing at least one of:
   a voltage over the controlled first source; and
   a voltage from the source node to the source node; and
   an output of (e.g. a current generated by) the controlled first source.
31. The transistor model of one of the clauses 1 to 31,
   wherein the controlled first source and a second source of the at least one controlled second source are coupled to each other by at least one of a first parameter of the at least one parameter and a second parameter of the at least one parameter;
   wherein the first parameter of the at least one parameter represents a potential difference of the source node and the drain node;
   wherein the second parameter of the at least one parameter represents an output of the controlled first source.
32. The transistor model of one of the clauses 1 to 31,
   wherein a second parameter of the at least one parameter controlling at least one of a controlled capacitance component and a second source of the at least one second controlled source represents the charge injection.
33. The transistor model of one of the clauses 1 32,
   wherein the second electrical network includes a controlled capacitance component coupled in parallel to the controlled first source and including a third source of the at least one controlled second source (e.g. for controlling a charge storage of the controlled capacitance component);
   wherein the controlled capacitance component represents a charge storage characteristic of the parasitic junction via the third source; and wherein the controlled capacitance component and the controlled first source are coupled to each other via the at least one parameter.
34. The transistor model of clause 33,
   wherein the controlled capacitance component includes a capacitor coupled serially to the third source;
   wherein the capacitor represents a charge storage capability of the parasitic junction.
35. The transistor model clause 34,
   wherein the controlled capacitance component includes a first resistor (e.g. R_capacitor) coupled serially to the capacitor, wherein the first resistor and the capacitor form an RC-circuit representing an energy dissipation characteristic of the parasitic capacitance
36. The transistor model of one of the clauses 33 to 35,
   wherein the controlled capacitance component includes a third electrical network configured to control the third source such that a capacity of the controlled capacitance component in the forward operation is less than in the reverse operation.
37. The transistor model of one of the clauses 33 to 36,
   wherein the controlled capacitance component includes a third electrical network configured to control the third source such that a voltage over a capacitor of the controlled capacitance component in the forward operation is less than in the reverse operation.
38. The transistor model of one of the clauses 36 or 37,
   wherein the third electrical network includes a fourth electric energy source controlled by a second parameter of the at least one parameter, e.g. the second parameter representing an output of the controlled first source (e.g. a current generated by the first current source)
39. The transistor model of one of the clauses 36 to 38,
   wherein the third electrical network includes an RC-circuit (e.g. R_B and C_b) representing a cross sectional area of the field effect transistor through which the parasitic capacitance is charged and/or discharged, wherein the RC-circuit defines a third parameter of the at least one parameter.
40. The transistor model of one of the clauses 1 to 39, further including:
   a second resistor (e.g. R_Socket) coupled between the drain node and the second electrical network, wherein the second resistor represents a cross sectional chip area of the field effect transistor.
41. The transistor model of one of the clauses 1 to 40, further including:
   a third resistor (e.g. R_pillar) coupled between the source node and the controlled first source and in parallel to the at least one controlled second source, wherein the third resistor represents a track resistance of the field effect transistor.
42. A method for a computer based determination of a characteristic of a transistor using a transistor model of one of the clauses 1 to 41.
43. A computer readable storage medium including code segments to be executed by a computer, wherein the code segments represent a transistor model of one of the clauses 1 to 41.
44. A device for a computer based determination of a characteristic of a transistor, wherein the device includes a processor configured to simulate a transistor based on a transistor model of one of the clauses 1 to 41.
45. A commutation circuit model for a computer based simulation of a commutation operation, wherein the commutation circuit model includes a transistor model of one of the clauses 1 to 41.
46. A database including at least one parameter set representing a field effect transistor, wherein the database is configured to set up a transistor model of one of one of the clauses 1 to 41.
47. A method for a computer based determination of a characteristic of a transistor, the method including:
   assigning a first electrical characteristic to a parasitic junction of the transistor;
   assigning at least one second electrical characteristic to a charge injection dependent parasitic impedance of the transistor;
   determining a model representing an electrical characteristic of the transistor using the first electrical characteristic and the second electrical characteristic;
   wherein the model represents a parallel connection of the parasitic junction and the parasitic impedance;
   coupling the first electrical characteristic and the at least one second electrical characteristic to each other via at least one parameter such that a charge carrier injection by the parasitic junction into the parasitic impedance is considered; and
   performing an electric network analysis using the model.
48. The method of clause 47,
   wherein at least one of the first electrical characteristic and the at least one second electrical characteristic represent a relationship of two parameters (e.g. of an electric voltage and an electric current).
49. The method of clause 47 or 48,
   wherein the electric network analysis includes at least one of a commutation operation and a reverse operation.
50. The method of one of the clauses 47 to 49,
   wherein the parasitic junction includes or is formed from a unipolar-junction of the transistor (e.g. a diode).
51. The method of one of the clauses 47 to 50,
   wherein the charge carrier injection reduces the parasitic impedance.
52. The method of one of the clauses 47 to 51,
   wherein the parasitic impedance includes at least one of a further parasitic junction and a capacitive impedance of the parasitic junction; and/or
   wherein the at least one second electric characteristic includes at least one electric characteristic representing a further parasitic junction, and an electric characteristic representing a capacitive impedance of the parasitic junction.
53. The method of clause 52,
   wherein the further parasitic junction includes more polar interfaces than the parasitic junction.
54. The transistor of clause 52 or 53,
   wherein the further parasitic junction includes or is formed from a bipolar-junction of the transistor.
55. The transistor of clause 54,
   wherein the carrier injection includes a base load of the parasitic bipolar-junction of the transistor.
56. The transistor model of one of the clauses 25 to 55,
   wherein the carrier injection includes charging the capacitive impedance of the parasitic junction.
57. The method of one of the clauses 47 to 56,
   wherein the at least one second electrical characteristic represents one or more (e.g. at least two) parasitic elements of the transistor;
   wherein the model represents a parallel connection of the at least two parasitic elements.
58. The method of one of the clauses 47 to 57,
   wherein a second electrical characteristic of the at least one second electrical characteristic is configured to represent a charge injection dependent current flow through a further parasitic junction.
59. The method of one of the clauses 47 to 58,
   wherein a third electrical characteristic of the at least one second electrical characteristic is configured to represent a charge injection dependent capacity of the parasitic junction.
60. The method of one of the clauses 47 to 59,
   wherein a third electrical characteristic of the at least one second electrical characteristic is configured such that a capacity of the parasitic junction in the forward operation is less than in the reverse operation.
61. The method of one of the clauses 47 to 60,
   wherein a third electrical characteristic of the at least one second electrical characteristic represents a controlled capacitance component.
62. The method of one of the clauses 47 to 61,
   wherein the first electrical characteristic and/or the second electrical characteristic are at least one of stored in and loaded from a database.
63. A computer readable storage medium including code segments,
   wherein the code segments are configured to perform a method of one of the clauses 47 to 62 when executed.
64. A device for a computer based determination of a characteristic of a transistor, wherein the device includes a processor configured to perform a method of one of the clauses 47 to 62.
65. A transistor model for a computer based simulation of a field effect transistor, the transistor model including:
   a first electrical network coupled between a drain node, a source node and a gate node, wherein the first electrical network is configured to represent an electrical characteristic of the field effect transistor in a forward operation;
   a second electrical network coupled parallel to the first electrical network and between the source node and the drain node, wherein the second electrical network is configured to represent an electrical characteristic of the field effect transistor at least one of a commutation operation and a reverse operation;
   wherein the second electrical network includes:
      a programmable first network element and a programmable second network element in parallel;
      wherein the first network element includes a first electrical characteristic representing a parasitic junction of the field effect transistor; and
      wherein the second network element includes at least one second electrical characteristic representing a parasitic impedance of the transistor,
      wherein the first electrical characteristic and the at least one second electrical characteristic are coupled to each other via at least one parameter such that a charge carrier injection by the parasitic junction into the parasitic impedance is considered.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A transistor model for a computer based simulation of a field effect transistor, the transistor model comprising:
a first electrical network coupled between a drain node, a source node and a gate node, wherein the first electrical network is configured to represent an electrical characteristic of the field effect transistor in a forward operation;
a second electrical network coupled parallel to the first electrical network and between the source node and the drain node, wherein the second electrical network is configured to represent an electrical characteristic of the field effect transistor in at least one of a commutation operation and a reverse operation;
wherein the second electrical network comprises:
a controlled first source representing a parasitic junction of the field effect transistor;
at least one controlled second source representing a charge injection dependent parasitic impedance of the field effect transistor;
wherein the controlled first source and the at least one controlled second source are coupled in parallel; and
wherein the controlled first source and the at least one controlled second source are coupled via at least one parameter such that a charge injection from the parasitic junction into the parasitic impedance is considered.

2. The transistor model of claim 1,
wherein the parasitic junction comprises a unipolar-junction of the transistor.

3. The transistor model of claim 1, wherein the at least one second controlled source comprises at least one of:
a second source representing a further parasitic junction; and
a third source representing a capacitive impedance of the parasitic junction.

4. The transistor model of claim 3,
wherein the further parasitic junction comprises more polar interfaces than the parasitic junction.

5. The transistor model of claim 1,
wherein an output of the controlled first source is controlled by a first parameter of the at least one parameter representing a potential difference of the source node and the drain node.

6. The transistor model of claim 1,
wherein an output of a second source of the at least one controlled second source is controlled by a second parameter of the at least one parameter representing an output of the controlled first source.

7. The transistor model of claim 1,
wherein the second electrical network comprises a controlled capacitance component coupled in parallel to the controlled first source and comprising a third source of the at least one controlled second source for controlling a charge storage of the controlled capacitance component;
wherein the controlled capacitance component represents a charge storage characteristic of the parasitic junction via the third source; and
wherein the controlled capacitance component and the controlled first source are coupled to each other via a second parameter of the at least one parameter representing an output of the controlled first source.

8. The transistor model of claim 7,
wherein the controlled capacitance component comprises a capacitor coupled serially to the third source; and
wherein the capacitor represents a charge storage capability of the parasitic junction.

9. The transistor model of claim 8,
wherein the controlled capacitance component comprises a first resistor coupled serially to the capacitor, wherein the first resistor and the capacitor form an RC-circuit representing an energy dissipation characteristic of the charge storage capability.

10. The transistor model of claim 7,
wherein the controlled capacitance component comprises a third electrical network configured to control the third source such that a capacity of the controlled capacitance component in the forward operation is less than in the reverse operation.

11. The transistor model of claim 10,
wherein the third electrical network comprises a fourth electric energy source controlled by a second parameter of the at least one parameter representing an output of the controlled first source.

12. The transistor model of claim 10,
wherein the third electrical network comprises an RC-circuit representing a cross sectional area of the field effect transistor through which the charge storage capability is charged and/or discharged, wherein the RC-circuit defines a third parameter of the at least one parameter.

13. The transistor model of claim 1, further comprising:
a second resistor coupled between the drain node and the second electrical network, wherein the second resistor represents a cross sectional chip area of the field effect transistor.

14. The transistor model of claim 1, further comprising:
a third resistor coupled between the source node and the controlled first source and in parallel to the at least one controlled second source, wherein the third resistor represents a track resistance of the field effect transistor.

15. A computer readable storage medium comprising code segments to be executed by a computer, wherein the code segments represent a transistor model, the transistor model comprising:
a first electrical network coupled between a drain node, a source node and a gate node, wherein the first electrical network is configured to represent an electrical characteristic of the field effect transistor in a forward operation;
a second electrical network coupled parallel to the first electrical network and between the source node and the drain node, wherein the second electrical network is configured to represent an electrical characteristic of the field effect transistor in at least one of a commutation operation and a reverse operation;
wherein the second electrical network comprises:
a controlled first source representing a parasitic junction of the field effect transistor;
at least one controlled second source representing a charge injection dependent parasitic impedance of the field effect transistor;
wherein the controlled first source and the at least one controlled second source are coupled in parallel; and
wherein the controlled first source and the at least one controlled second source are coupled via at least one parameter such that a charge injection from the parasitic junction into the parasitic impedance is considered.

16. A device for a computer based determination of a characteristic of a transistor, wherein the device comprises a processor configured to simulate a transistor based on a transistor model, the transistor model comprising:
a first electrical network coupled between a drain node, a source node and a gate node, wherein the first electrical network is configured to represent an electrical characteristic of the field effect transistor in a forward operation;
a second electrical network coupled parallel to the first electrical network and between the source node and the drain node, wherein the second electrical network is configured to represent an electrical characteristic of the field effect transistor in at least one of a commutation operation and a reverse operation;
wherein the second electrical network comprises:
a controlled first source representing a parasitic junction of the field effect transistor;
at least one controlled second source representing a charge injection dependent parasitic impedance of the field effect transistor;
wherein the controlled first source and the at least one controlled second source are coupled in parallel; and
wherein the controlled first source and the at least one controlled second source are coupled via at least one parameter such that a charge injection from the parasitic junction into the parasitic impedance is considered.

17. A database comprising at least one parameter set representing a field effect transistor, wherein the database is configured to set up a transistor model, comprising:
a first electrical network coupled between a drain node, a source node and a gate node, wherein the first electrical network is configured to represent an electrical characteristic of the field effect transistor in a forward operation;
a second electrical network coupled parallel to the first electrical network and between the source node and the drain node, wherein the second electrical network is configured to represent an electrical characteristic of the field effect transistor in at least one of a commutation operation and a reverse operation;
wherein the second electrical network comprises:
a controlled first source representing a parasitic junction of the field effect transistor;
at least one controlled second source representing a charge injection dependent parasitic impedance of the field effect transistor;
wherein the controlled first source and the at least one controlled second source are coupled in parallel; and
wherein the controlled first source and the at least one controlled second source are coupled via at least one parameter such that a charge injection from the parasitic junction into the parasitic impedance is considered.

18. A method for a computer based determination of a characteristic of a transistor, the method comprising:
assigning a first electrical characteristic to a parasitic junction of the transistor;
assigning at least one second electrical characteristic to a charge injection dependent parasitic impedance of the transistor;
determining a model representing an electrical characteristic of the transistor using the first electrical characteristic and the second electrical characteristic;
wherein the model represents a parallel connection of the parasitic junction and the parasitic impedance;
coupling the first electrical characteristic and the at least one second electrical characteristic to each other via at least one parameter such that a charge carrier injection by the parasitic junction into the parasitic impedance is considered; and
performing an electric network analysis using the model.

19. The method of claim 18,
wherein a second electrical characteristic of the at least one second electrical characteristic is configured to represent a charge injection dependent current flow through a further parasitic junction.

20. The method of claim 18,
wherein a third electrical characteristic of the at least one second electrical characteristic is configured such that a capacity of the parasitic junction in a forward operation of the transistor is less than in a reverse operation of the transistor.

21. A computer readable storage medium comprising code segments, wherein the code segments are configured to perform a method for a computer based determination of a characteristic of a transistor, the method comprising:
assigning a first electrical characteristic to a parasitic junction of the transistor;
assigning at least one second electrical characteristic to a charge injection dependent parasitic impedance of the transistor;
determining a model representing an electrical characteristic of the transistor using the first electrical characteristic and the second electrical characteristic;
wherein the model represents a parallel connection of the parasitic junction and the parasitic impedance;
coupling the first electrical characteristic and the at least one second electrical characteristic to each other via at least one parameter such that a charge carrier injection by the parasitic junction into the parasitic impedance is considered; and
performing an electric network analysis using the model.

22. A device for a computer based determination of a characteristic of a transistor, wherein the device comprises a processor configured to perform a method for a computer based determination of a characteristic of a transistor, the method comprising:
assigning a first electrical characteristic to a parasitic junction of the transistor;
assigning at least one second electrical characteristic to a charge injection dependent parasitic impedance of the transistor;
determining a model representing an electrical characteristic of the transistor using the first electrical characteristic and the second electrical characteristic;
wherein the model represents a parallel connection of the parasitic junction and the parasitic impedance;
coupling the first electrical characteristic and the at least one second electrical characteristic to each other via at least one parameter such that a charge carrier injection by the parasitic junction into the parasitic impedance is considered; and
performing an electric network analysis using the model.

23. A transistor model for a computer based simulation of a field effect transistor, the transistor model comprising:
a first electrical network coupled between a drain node, a source node and a gate node, wherein the first electrical network is configured to represent an electrical characteristic of the field effect transistor in a forward operation;
a second electrical network coupled parallel to the first electrical network and between the source node and the drain node, wherein the second electrical network is configured to represent an electrical characteristic of the field effect transistor at least one of a commutation operation and a reverse operation;
wherein the second electrical network comprises:
a programmable first network element and a programmable second network element in parallel;
wherein the first network element comprises a first electrical characteristic representing a parasitic junction of the field effect transistor; and
wherein the second network element comprises at least one second electrical characteristic representing a parasitic impedance of the transistor,
wherein the first electrical characteristic and the at least one second electrical characteristic are coupled to each other via at least one parameter such that a charge carrier injection by the parasitic junction into the parasitic impedance is considered.
